(19) United States
(12) Patent Application Publication
(10) Pub. No.: US 2026/0114141 A1
(43) Pub. Date: Apr. 23, 2026

(54) DISPLAY APPARATUS AND ELECTRONIC DEVICE INCLUDING THE SAME

(71) Applicant: Samsung Display Co., Ltd., Yongin-si (KR)

(72) Inventors: Hanbum Kwon, Yongin-si (KR); Eunbyul Kim, Yongin-si (KR); Youngmin Ahn, Yongin-si (KR)

(21) Appl. No.: 19/293,441

(22) Filed: Aug. 7, 2025

(30) Foreign Application Priority Data
Oct. 17, 2024 (KR) 10-2024-0142307

(51) Int. Cl. H10K 59/131; H10K 59/124; H10K 59/88

(52) U.S. Cl. CPC H10K 59/131; H10K 59/124; H10K 59/88

(57) ABSTRACT

A display apparatus and an electronic device including the display apparatus are disclosed. The display apparatus may include a substrate divided into a display area and a peripheral area around the display area, the peripheral area including a pad area in which a first conductive pad and a first dummy pad are provided, a gate layer on the substrate, an interlayer insulating film on the gate layer, and a first conductive layer on the interlayer insulating film, wherein the first conductive pad includes a first pad layer on the substrate, a second pad layer on the first pad layer, a third pad layer on the second pad layer, and a first-1 buffer pad on the second pad layer, wherein the first dummy pad includes a first dummy pad layer on the substrate and a second dummy pad layer on the first dummy pad layer.

### CROSS-REFERENCE TO RELATED APPLICATION

The present application claims priority to and the benefit of Korean Patent Application No. 10-2024-0142307, filed on October 17, 2024, in the Korean Intellectual Property Office, the entire disclosure of which is incorporated herein by reference.

### BACKGROUND

### Field

One or more embodiments of the present disclosure relate to a display apparatus and an electronic device including the display apparatus, and, for example, to a display apparatus, in which the position of a polymer pad may be easily determined, and an electronic device including the display apparatus.

### Description of the Related Art

Display apparatuses display images by receiving information about the images. The display apparatuses may be used as displays of small products, such as mobile phones, and/or as displays of large products, such as televisions.

The display apparatuses include a plurality of pixels that receive electrical signals and emit light to display images externally. Each pixel includes a light-emitting element and, for example, organic light-emitting display apparatuses may include organic light-emitting diodes (OLEDs) as light-emitting elements. The organic light-emitting display apparatuses include a thin-film transistor and an organic light-emitting diode on a substrate, and the organic light-emitting diode operates by self-emitting light.

### SUMMARY

One or more aspects of embodiments of the present disclosure are directed toward a display apparatus in which quality inspection may be easily performed and an electronic device including the display apparatus. However, these embodiments are provided as examples so that this disclosure will be thorough and complete, and embodiments of the present disclosure are not limited thereto.

Additional aspects of embodiments will be set forth in part in the description which follows and, in part, will be apparent from the description, or may be learned by practice of the presented embodiments of the disclosure.

According to one or more embodiments, a display apparatus includes a substrate divided into a display area and a peripheral area around (e.g., surrounding) the display area, the peripheral area including a pad area in which a first conductive (e.g., electrically conductive) pad and a first dummy pad are disposed or provided, a gate layer on the substrate, an interlayer insulating (e.g., electrically insulating) film on the gate layer, and a first conductive (e.g., electrically conductive) layer on the interlayer insulating film. The first conductive pad may include a first pad layer disposed or provided on the substrate and including substantially the same material as the gate layer, a second pad layer disposed or provided on the first pad layer and including substantially the same material as the interlayer insulating film, a third pad layer disposed or provided on the second pad layer and including substantially the same material as the first pad layer, and a first-1 buffer pad on the third pad layer. The first dummy pad may include a first dummy pad layer disposed or provided on the substrate and including substantially the same material as the gate layer, and a second dummy pad layer on the first dummy pad layer. The first dummy pad layer may include a first-1 bridge area that corresponds to a position of the first-1 buffer pad and an edge area around (e.g., surrounding) the first-1 bridge area. The second dummy pad layer may be on the first dummy pad layer and may include substantially the same material as the interlayer insulating film.

The first-1 bridge area may be on a first-1 virtual line that passes the first-1 buffer pad.

The first dummy pad may include a dummy opening defined by the first-1 bridge area and the edge area.

A second conductive (e.g., electrically conductive) pad may further be in the pad area, and the first dummy pad may be disposed or provided on a straight line (e.g., a substantially straight line) as the first conductive pad and the second conductive pad.

On a plane (e.g., in a plan view), the first conductive pad may be between the first dummy pad and the second conductive pad.

On a plane (e.g., in a plan view), the first dummy pad may be between the first conductive pad and the second conductive pad.

A second dummy pad may further be in the pad area on the straight line as the first conductive pad and the second conductive pad.

On a plane (e.g., in a plan view), the first conductive pad and the second conductive pad may be between the first dummy pad and the second dummy pad.

The first conductive pad may further include a first-2 buffer pad on the second pad layer.

The first dummy pad layer may further include a first-2 bridge area that corresponds to a position of the first-2 buffer pad, wherein the edge area is around (e.g., surrounds) the first-1 bridge area and the first-2 bridge area.

The first-2 bridge area may pass the first-2 buffer pad and be on a first-2 virtual line parallel (e.g., substantially parallel) to the first-1 virtual line.

Each of the first-1 buffer pad and the first-2 buffer pad may comprise a polymer.

The display apparatus may further include a second conductive (e.g., electrically conductive) layer on the first conductive layer, wherein the first conductive pad further includes a fourth pad layer disposed or provided on the first-1 buffer pad and including substantially the same material as the second conductive layer.

The fourth pad layer may cover an upper surface and an outer surface of the first-1 buffer pad.

The second pad layer may include at least one pad opening, and the third pad layer may contact the first pad layer via the at least one pad opening.

According to one or more embodiments, a display apparatus includes a substrate including a display area and a peripheral area around (e.g., surrounding) the display area, a first conductive (e.g., electrically conductive) pad disposed or provided in the peripheral area and including a first buffer pad, and a first dummy pad in the peripheral area. The first dummy pad may include a first dummy pad layer on the substrate, and a second dummy pad layer on the first dummy pad layer. The first dummy pad layer may include a first bridge area that corresponds to a position of the first buffer pad, a second bridge area that corresponds to a position of a second buffer pad included in another display apparatus, and an edge area around (e.g., surrounding) the first bridge area and the second bridge area.

The display apparatus may include a gate layer on the substrate, and an interlayer insulating (e.g., electrically insulating) film on the gate layer, wherein the first dummy pad layer may include substantially the same material as the gate layer, and the second dummy pad layer may include substantially the same material as the interlayer insulating film.

The second buffer pad may be included in a second conductive (e.g., electrically conductive) pad that is included in the other display apparatus.

If (e.g., when) the first dummy pad, the first conductive pad, and the second conductive pad are disposed or provided side by side, the first bridge area may be on a first virtual line that passes the first buffer pad, and the second bridge area may be on a second virtual line that passes the second buffer pad and that is parallel (e.g., substantially parallel) to the first virtual line.

According to one or more embodiments, an electronic device includes a memory to store instructions, a processor to generate control signals based on the instructions, and a display apparatus to display a screen based on the control signals. The display apparatus may include a substrate divided into a display area and a peripheral area around (e.g., surrounding) the display area, the peripheral area including a pad area in which a first conductive (e.g., electrically conductive) pad and a first dummy pad are disposed or provided, a gate layer on the substrate, an interlayer insulating (e.g., electrically insulating) film on the gate layer, and a first conductive (e.g., electrically conductive) layer on the interlayer insulating film. The first conductive pad may include a first pad layer disposed or provided on the substrate and including substantially the same material as the gate layer, a second pad layer disposed or provided on the first pad layer and including substantially the same material as the interlayer insulating film, a third pad layer disposed or provided on the second pad layer and including substantially the same material as the first pad layer, and a first-1 buffer pad on the third pad layer. The first dummy pad may include a first dummy pad layer and a second dummy pad layer on the first dummy pad layer. The first dummy pad layer may be disposed or provided on the substrate and include substantially the same material as the gate layer, a first-1 bridge area that corresponds to a position of the first-1 buffer pad, and an edge area around (e.g., surrounding) the first-1 bridge area. The second dummy pad layer may include a second dummy pad layer disposed or provided on the first dummy pad layer and including substantially the same material as the interlayer insulating film.

According to one or more embodiments, an electronic device includes a memory to store instructions, a processor to generate control signals based on the instructions, and a display apparatus to display a screen based on the control signals. The display apparatus may include a substrate including a display area and a peripheral area around (e.g., surrounding) the display area, a first conductive (e.g., electrically conductive) pad disposed or provided in the peripheral area and including a first buffer pad, and a first dummy pad in the peripheral area. The first dummy pad may include a first dummy pad layer on the substrate and a second dummy pad layer on the first dummy pad layer. The first dummy pad layer may include a first bridge area that corresponds to a position of the first buffer pad, a second bridge area that corresponds to a position of a second buffer pad included in another display apparatus, and an edge area around (e.g., surrounding) the first bridge area and the second bridge area.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is an example of a plan view schematically illustrating a display panel and a connection circuit board of a display apparatus according to one or more embodiments;

FIGS. 2 and 3 are examples of plan views schematically illustrating a display panel and a connection circuit board of a display apparatus according to one or more embodiments;

FIG. 4 schematically illustrates a manufacturing process of a first conductive (e.g., electrically conductive) pad of FIGS. 1-3;

FIG. 5 is a schematic cross-sectional view of the first conductive pad taken along the line A-A' of FIG. 4;

FIG. 6 is a schematic cross-sectional view of the first conductive pad taken along the line B-B' of FIG. 4;

FIG. 7 schematically illustrates a manufacturing process of a first dummy pad of FIGS. 1-3;

FIG. 8 is a schematic cross-sectional view of the dummy pad of operation S3 taken along the line C-C' of FIG. 7;

FIG. 9 is a plan view schematically illustrating an example of a method by which the first dummy pad layer of FIGS. 7 and 8 indicates the position of the buffer pad;

FIG. 10 is a plan view schematically illustrating an example of a method by which the first dummy pad layer of FIGS. 7 and 8 indicates the position of the buffer pad;

FIG. 11 is a schematic cross-sectional view of the first conductive pad and a signal pad of FIG. 1;

FIG. 12 is a schematic cross-sectional view of a portion of a pixel of FIG. 1; and

FIG. 13 is a conceptual diagram schematically illustrating an electronic device including the display apparatus of FIGS. 1-12.

### DETAILED DESCRIPTION

Reference will be made in more detail to one or more embodiments, examples of which are illustrated in the accompanying drawings, wherein like reference numerals refer to like elements throughout the accompanying drawings and the written description, and duplicative descriptions thereof may not be provided in the specification. In this regard, the subject matter of the present disclosure may be embodied in different forms and should not be construed as being limited to one or more embodiments set forth herein. Rather, these embodiments are provided as examples, by referring to the figures, to explain the aspects and features of the present disclosure to those skilled in the art.

As used herein, the term "and/or" includes any and all combinations of one or more of the associated listed items. Throughout the disclosure, the expression "at least one of a, b, or c" or "at least one selected from among a, b, and c" indicate only a, only b, only c, both a and b, both a and c, both b and c, all of a, b, and c, or variations thereof.

The above and other aspects and features of certain embodiments of the present disclosure will become more apparent to one of ordinary skill in the art to which the present disclosure pertains by referencing the detailed description of the present disclosure given. The subject matter of the present disclosure may, however, be embodied in different forms and should not be construed as being limited to one or more embodiments set forth herein.

One or more embodiments of the present disclosure will be described herein in more detail with reference to the accompanying drawings. Those elements that are substantially the same or are in correspondence are rendered the same reference numeral regardless of the figure number, and redundant descriptions thereof may not be provided.

As used herein, the terms "substantially," "about," and similar terms are used as terms of approximation and not as terms of degree and are intended to account for the inherent deviations in measured or calculated values that would be recognized by those of ordinary skill in the art.

The use of "may" if (e.g., when) describing embodiments of the present disclosure refers to “one or more embodiments of the present disclosure.”

As used herein, the terms "use," "using," and "used" may be considered synonymous with the terms "utilize," "utilizing," and "utilized," respectively. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

It will be understood that, although the terms “first,” “second,” “third,” and/or the like may be used herein to describe one or more elements, components, regions, layers, and/or sections, these elements, components, regions, layers, and/or sections should not be limited by these terms. These terms are used to distinguish one element, component, region, layer, or section from another element, component, region, layer, or section. Thus, a first element, a first component, a first region, a first layer, or a first section as described herein may be termed a second element, a second component, a second region, a second layer, or a second section, without departing from the spirit and scope of the present disclosure.

In one or more embodiments, as used herein, the singular expressions "a," "an," and "the" are intended to include the plural forms as well, unless the context clearly indicates otherwise.

It will be understood that if (e.g., when) an element, such as a layer, a film, a region, or a plate, is referred to as being "on" another element, the element may be directly on the other element or intervening elements may be present therebetween.

The sizes of elements in the drawings may be exaggerated or reduced for convenience of description. For example, because the sizes and thicknesses of elements in the drawings may be arbitrarily illustrated for convenience of description, the embodiments of the present disclosure are not limited thereto.

It will be further understood that the terms “has,” “include,” “having,” and/or "including" used herein specify the presence of stated features or components, but do not preclude the presence or addition of one or more other features or components.

If (e.g., when) a certain embodiment may be implemented differently, a specific process order may be performed differently from the described order. For example, two consecutively described processes may be performed substantially at the same time or performed in an order opposite to the described order.

In the present disclosure, "A and/or B" denotes only A, only B, or both A and B. Also, "at least one of A and B" denotes only A, only B, or both A and B.

In one or more embodiments, it will be understood that if (e.g., when) an element, an area, or a layer is referred to as being connected to another element, area, or layer, it may be directly and/or indirectly connected to the other element, area, or layer. For example, in the present disclosure, if (e.g., when) a layer, a region, a component, and/or the like is electrically connected to another layer, region, component, and/or the like, the layer, the region, the component, and/or the like may be directly electrically connected thereto and/or may be indirectly electrically connected thereto with an intervening layer, region, component, and/or the like therebetween.

In one or more embodiments, the x-axis, the y-axis, and the z-axis are not limited to three axes of the rectangular coordinate system, and may be interpreted in a broader sense. For example, the x-axis, the y-axis, and the z-axis may be normal (e.g., substantially perpendicular) to one another, or may represent different directions that are not perpendicular to one another.

Hereinafter, a display apparatus and an electronic device including the display apparatus according to one or more embodiments are described in more detail.

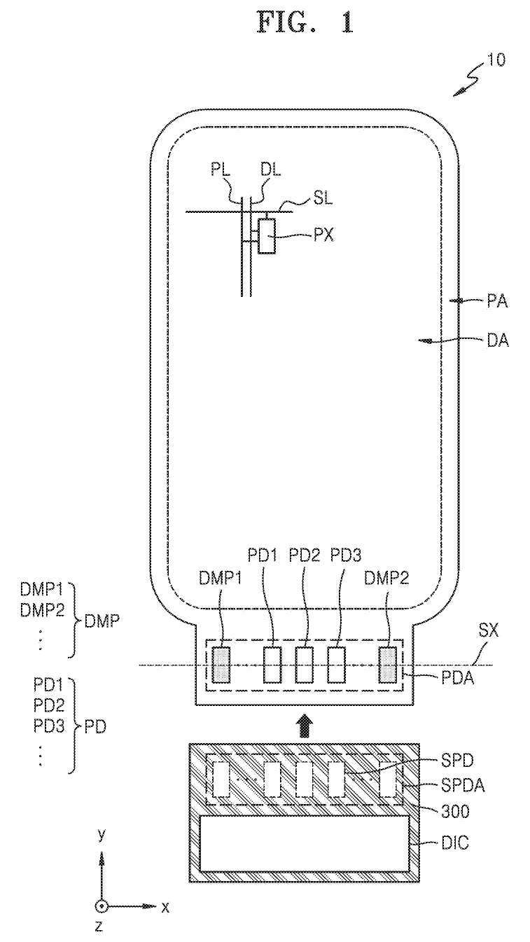

FIG. 1 is an example of a plan view schematically illustrating a display panel 10 and a connection circuit board 300 of a display apparatus according to one or more embodiments.

As shown in FIG. 1, the display apparatus according to one or more embodiments may include the display panel 10. The display apparatus may be any suitable apparatus that includes the display panel 10.

The display apparatus may display a moving image and/or a still image and may be used as a display screen for portable electronic devices, such as mobile phones, smart phones, tablet personal computers, mobile communication terminals, electronic notebooks, electronic books, portable multimedia players (PMP), navigation devices, and ultra mobile PCs (UMPC), as well as one or more suitable products, such as televisions, laptops, monitors, billboards, and internet of things (IOT) devices. In one or more embodiments, the display apparatus according to one or more embodiments may be used in wearable devices, such as a smart watch, a watch phone, a glasses-type or kind display, and a head mounted display (HMD). In one or more embodiments, the display apparatus according to one or more embodiments may be used as a dashboard of a vehicle, a center information display (CID) in a center fascia or the dashboard of a vehicle, a mirror display that replaces the rear view mirror and/or the side view mirror of a vehicle, and a display on the rear of the front seat for entertainment for back seat passengers of a vehicle.

The display panel 10 may include a display area DA and a peripheral area PA outside the display area DA. The display area DA may be a portion where an image is displayed, and a plurality of subpixels may be in the display area DA. If (e.g., when) viewed in a direction substantially perpendicular to the display panel 10, the display area DA may have any of one or more suitable shapes, such as a circular shape (e.g., a substantially circular shape), an elliptical shape (e.g., a substantially elliptical shape), a polygonal shape (e.g., a substantially polygonal shape), or a shape of a set or predetermined figure. In FIG. 1, the display area DA may have a substantially rectangular shape having round corners.

The peripheral area PA may be outside the display area DA. The peripheral area PA may be an area where no image is displayed and may refer to an area around (e.g., surrounding) the display area DA.

The display area DA may be a portion to display an image, in which a plurality of pixels PX may be disposed or provided. Each subpixel PX may include a display element, such as an organic light-emitting diode. Each subpixel PX may emit, for example, red, green, or blue light. Each subpixel PX may be connected to a pixel circuit including a thin-film transistor (TFT), a storage capacitor, and/or the like. The pixel circuit may be connected to a scan line SL to transmit a scan signal, a data line DL that crosses the scan line SL and that is provided to transmit a data signal, a driving voltage line PL to supply a driving voltage, and/or the like. The data line DL and the driving voltage line PL may extend in the y-axis direction (hereinafter, the first direction), and the scan line SL may extend in the x-axis direction (hereinafter, the second direction).

Each subpixel PX may emit light having a luminance that corresponds to an electrical signal from the pixel circuit to which the pixel PX is electrically connected. The display area DA may display a certain image through light emitted from each subpixel PX. For reference, each subpixel PX may be defined as an emission area that emits light of any one color selected from among red, green, and blue.

The peripheral area PA, in which the subpixel PX is not disposed or provided, may not display an image. A power supply wiring to drive each subpixel PX and/or the like may be in the peripheral area PA. In one or more embodiments, a conductive pad PD may be in the peripheral area PA, and a driving chip DIC, such as a printed circuit board or a driver IC, may be electrically connected to the conductive pad PD in the peripheral area PA.

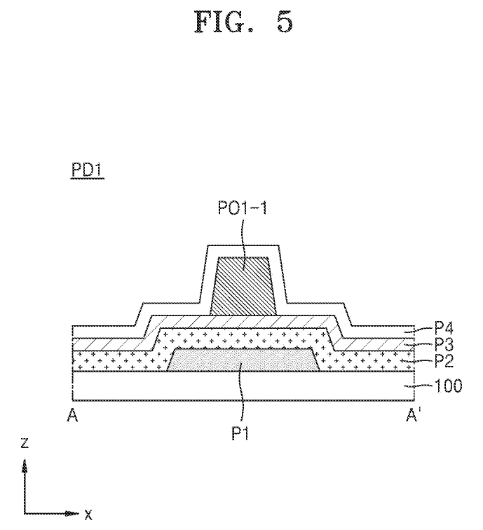

Because the display panel 10 includes a substrate 100 (refer to FIGS. 5, 6, 8 and 12; substantially the same applies hereinafter) as described in one or more embodiments, the substrate 100 may include the display area DA and the peripheral area PA as described in one or more embodiments. For convenience of explanation, the substrate 100 or display panel 10 may be described as including the display area DA and the peripheral area PA.

A pad area PDA wherein a conductive pad PD is disposed or provided may be defined on a side of the peripheral area PA. The conductive pad PD may include a plurality of conductive (e.g., electrically conductive) pads. The pad area PDA may be electrically connected to the connection circuit board 300. For example, the conductive pad PD may be electrically connected to or in direct contact with signal pads SPD on the lower surface of the connection circuit board 300. The conductive pad PD of the pad area PDA may exchange electrical signals with the signal pad SPD.

For example, the conductive pad PD may include a first conductive pad PD1, a second conductive pad PD2, and a third conductive pad PD3. For example, the first conductive pad PD1, the second conductive pad PD2, and the third conductive pad PD3 may be in the pad area PDA. The first conductive pad PD1, the second conductive pad PD2, and the third conductive pad PD3 may all have substantially the same specification. For example, the first conductive pad PD1, the second conductive pad PD2, and the third conductive pad PD3 may be on a straight line SX. The straight line SX may refer to a virtual line that extends in an x-axis direction. For convenience of explanation, only the first conductive pad PD1, the second conductive pad PD2, and the third conductive pad PD3 are illustrated in FIG. 1, but other conductive (e.g., electrically conductive) pads may be further disposed or provided in the pad area PDA, and the conductive pad PD may further include other conductive (e.g., electrically conductive) pads.

A signal pad area SPDA in which the signal pad SPD is disposed or provided may be defined on the lower surface of the connection circuit board 300. The signal pad SPD may include a plurality of signal pads. The signal pad SPD of the signal pad area SPDA may protrude downward. On the other hand, the signal pad SPD of the signal pad area SPDA may protrude upward.

The driving chip DIC may be in the connection circuit board 300. The driving chip DIC may include an integrated circuit that drives the display panel 10. The integrated circuit may include a data driving integrated circuit to generate a data signal, but embodiments of the present disclosure are not limited thereto. The driving chip DIC may be mounted on the connection circuit board 300.

A dummy pad DMP may further be in the pad area PDA. The dummy pad DMP may include a plurality of dummy pads. For example, the dummy pad DMP may include a first dummy pad DMP1 and a second dummy pad DMP2. For convenience of explanation, only the first dummy pad DMP1 and the second dummy pad DMP2 are illustrated in FIG. 1, but other dummy pads may be further disposed or provided in the pad area PDA and the dummy pad DMP may further include other dummy pads.

For example, the first dummy pad DMP1 and the second dummy pad DMP2 may be on the straight line SX on a plane (e.g., in a plan view). In a plan view, the conductive pad PD may be between the first dummy pad DMP1 and the second dummy pad DMP2. The dummy pad DMP and the conductive pad PD may be placed on the straight line SX on a plane (e.g., in a plan view).

Hereinafter, although an organic light-emitting display apparatus is described as an example of the display apparatus according to one or more embodiments, the display apparatus of the present disclosure is not limited thereto. In one or more embodiments, the display apparatus of the present disclosure may be an inorganic light-emitting display apparatus or a quantum dot light-emitting display apparatus. For example, an emission layer of a display apparatus according to one or more embodiments may include an organic material and/or an inorganic material. Also, the display apparatus may include an emission layer and a quantum dot layer in a path of light emitted from the emission layer.

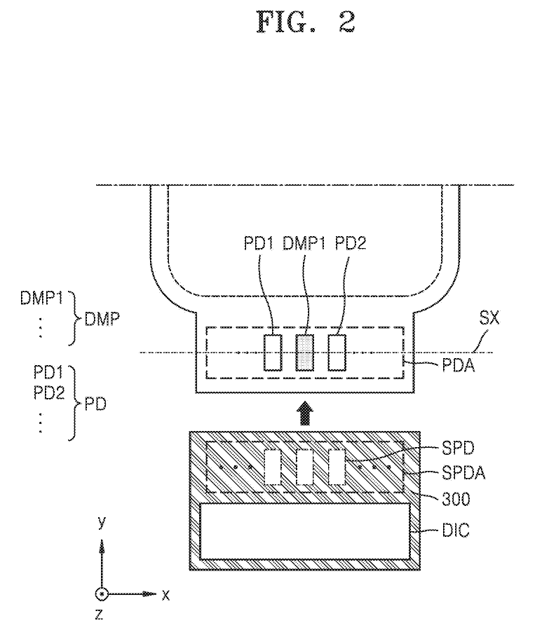

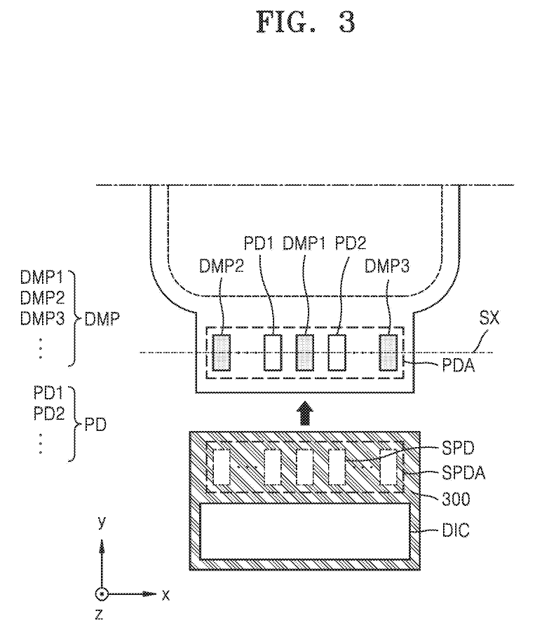

FIGS. 2 and 3 are examples of plan views schematically illustrating a display panel and a connection circuit board of a display apparatus according to one or more embodiments.

For reference, FIGS. 2 and 3 mainly or predominantly illustrate the pad area for convenience of explanation, and any content that is substantially identical or overlapping with the description of FIG. 1 may not be provided.

As illustrated in FIG. 2, the first dummy pad DMP1 may be between the first conductive pad PD1 and the second conductive pad PD2. For example, the first dummy pad DMP1 may be between the conductive pads PD. For convenience of explanation, only the first dummy pad DMP1, the first conductive pad PD1, and the second conductive pad PD2 are illustrated in FIG. 2, but in one or more embodiments, other dummy pads may be further disposed or provided between the conductive pads PD, and other conductive (e.g., electrically conductive) pads may be further disposed or provided in the pad area PDA. The dummy pad DMP may be on the straight line SX as the conductive pads PD.

As illustrated in FIG. 3, the first dummy pad DMP1 may be between the conductive pads PD. For example, the first dummy pad DMP1 may be between the first conductive pad PD1 and the second conductive pad PD2. For example, the second dummy pad DMP2 and the third dummy pad DMP3 may be at the outermost edge of the pad area PDA. For example, the conductive pad PD may be between the second dummy pad DMP2 and the third dummy pad DMP3. For example, the first conductive pad PD1, the second conductive pad PD2, and the first dummy pad DMP1 may be between the second dummy pad DMP2 and the third dummy pad DMP3. Other conductive pads PD may further be disposed or provided between the second dummy pad DMP2 and the third dummy pad DMP3. The dummy pads DMP may be on the straight line SX as the conductive pads PD.

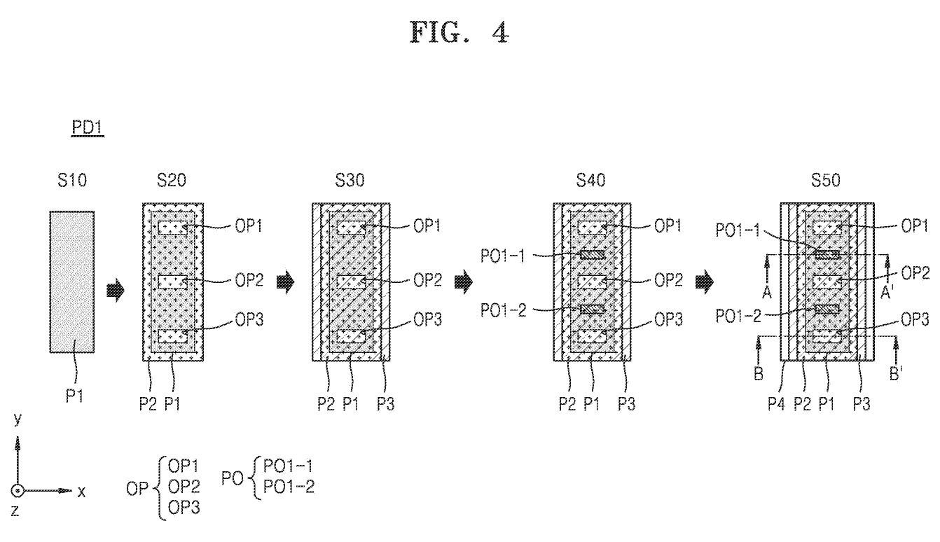

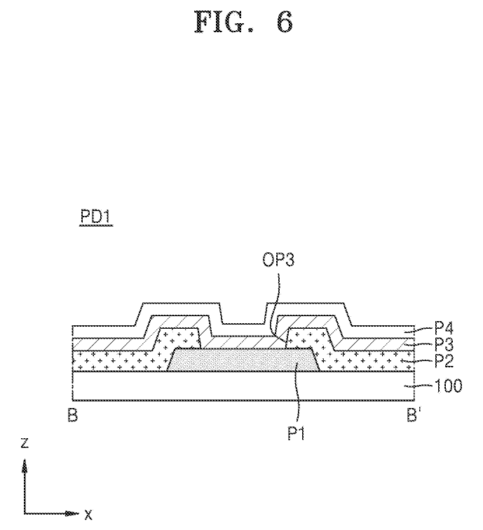

FIG. 4 schematically illustrates a manufacturing process of the first conductive pad PD1 of FIGS. 1 to 3, FIG. 5 is a schematic cross-sectional view of the first conductive pad PD1 taken along the line A-A' of FIG. 4, and FIG. 6 is a schematic cross-sectional view of the first conductive pad PD1 taken along the line B-B' of FIG. 4.

For convenience of explanation, the manufacturing process of only one or more of the components of the display apparatus is illustrated in FIG. 4, and the contents with respect to the other components may be clearly inferred by those of ordinary skill in the art from the entire description of the present disclosure.

FIG. 4 is described using the first conductive pad PD1 among the conductive pads PD for convenience of explanation, and the description of other conductive (e.g., electrically conductive) pads, such as the second conductive pad PD2 and the third conductive pad PD3, may be substituted with the description of the first conductive pad PD1.

As illustrated in FIG. 4, the first conductive pad PD1 may include a first pad layer P1, a second pad layer P2, a third pad layer P3, a buffer pad PO, and a fourth pad layer P4, which may be sequentially stacked.

The first conductive pad PD1 may be manufactured through the methods as described in one or more embodiments. Other conductive (e.g., electrically conductive) pads, such as the second conductive pad PD2, may also be manufactured through substantially the same methods, and for convenience of explanation, the manufacturing method is described based on the first conductive pad PD1. For example, the manufacturing may include:

forming or providing the first pad layer P1 on the substrate 100 (S10);

forming or providing the second pad layer P2 on the first pad layer P1 to cover the first pad layer P1 (S20);

forming or providing the third pad layer P3 on the second pad layer P2 (S30);

forming or providing the buffer pad PO on the third pad layer P3 (S40); and

forming or providing the fourth pad layer P4 on the buffer pad PO (S50).

The forming or providing of the first pad layer P1 (S10) may include forming or providing the first pad layer (P1) having a set or predetermined shape and/or a set or predetermined pattern on the substrate 100. The first pad layer P1 may be formed or provided through chemical vapor deposition (CVD) and/or atomic layer deposition (ALD). The first pad layer P1 may be formed or provided to have a set or predetermined shape and/or a set or predetermined pattern through a dry etching process and/or a wet etching process using a mask.

The forming or providing of the second pad layer P2 (S20) may include forming or providing the second pad layer P2 on the first pad layer P1 and forming or providing a pad opening OP of a set or predetermined size in the second pad layer P2. The second pad layer P2 may cover the entire first pad layer P1 except for the portion where the pad opening OP is formed or provided. The second pad layer P2 may be formed or provided through CVD and/or ALD.

The pad opening OP formed or provided in the second pad layer P2 may include at least one pad opening. Although a first pad opening OP1, a second pad opening OP2, and a third pad opening OP3 are illustrated in FIG. 4, they are only examples for convenience of explanation, and other pad openings may be further formed or provided in the second pad layer P2. The pad opening OP may be formed or provided to have a set or predetermined shape and/or a set or predetermined pattern through a dry etching process and/or a wet etching process using a mask.

As a result of forming or providing the pad opening OP, a portion of the upper surface of the first pad layer P1 may be exposed upward (e.g., toward the z-axis direction). A portion of the upper surface of the first pad layer P1 exposed upward may be in direct contact with the third pad layer P3 formed or provided later.

The forming or providing of the third pad layer P3 (S30) may include forming or providing the third pad layer P3 on the second pad layer P2 through CVD and/or ALD. The third pad layer P3 may be in direct contact with the first pad layer P1 through the pad opening OP. The third pad layer P3 may be electrically connected to the first pad layer P1 through the pad opening OP.

The forming or providing of the buffer pad PO (S40) may include forming or providing a polymer layer on the third pad layer P3 and forming or providing the buffer pad PO in a set or predetermined position of the formed or provided polymer layer by a dry etching process and/or a wet etching process using a mask. For example, on a plane (e.g., in a plan view), the width of the buffer pad PO in the x direction may be less than the width of the pad opening OP in the x direction. The first-1 buffer pad PO1-1 and the first-2 buffer pad PO1-2 may be apart in the y-axis direction and the first pad opening OP1 to the third pad opening OP3 may be apart in the y-axis direction.

The forming or providing of the fourth pad layer P4 (S50) may include forming or providing the fourth pad layer P4 through CVD and/or ALD to cover the buffer pad PO. The fourth pad layer P4 may be in direct contact with the third pad layer P3 and electrically connected to the third pad layer P3. The fourth pad layer P4 may be electrically connected to the first pad layer P1 through the third pad layer P3 that is in direct contact with the first pad layer P1.

As illustrated in FIG. 4, the first pad layer P1 may be on the substrate 100. The first pad layer P1 may include substantially the same material as and be formed or provided concurrently (e.g., simultaneously) with a gate layer 120 as described in one or more embodiments. The first pad layer P1 may include a conductive (e.g., electrically conductive) material. The first pad layer P1 and the gate layer 120 may be formed or provided through substantially the same process.

The second pad layer P2 may be on the first pad layer P1. The second pad layer P2 may cover the upper surface and the outer surface of the first pad layer P1. The second pad layer P2 and an interlayer insulating film 103 as described in one or more embodiments may include substantially the same material and be formed or provided concurrently (e.g., simultaneously). The second pad layer P2 may include an insulating (e.g., electrically insulating) material. The second pad layer P2 and the interlayer insulating film 103 may be formed or provided through substantially the same process.

The third pad layer P3 may be on the second pad layer P2. The third pad layer P3 may cover the upper surface of the second pad layer P2. The third pad layer P3 may include substantially the same material as and be formed or provided concurrently (e.g., simultaneously) with a first conductive layer 130 as described in one or more embodiments. The third pad layer P3 may include a conductive (e.g., electrically conductive) material. The third pad layer P3 and the first conductive layer 130 may be formed or provided through substantially the same process.

As illustrated in FIG. 4, the buffer pad PO of FIG. 4 may be on the third pad layer P3. For example, the buffer pad PO may include at least one buffer pad. For example, the buffer pad PO may include a plurality of buffer pads PO1-1 and PO1-2. For example, the buffer pad PO may be a polymer pad. A buffer pad PO may include polymer and have as much elasticity as desired or required. The buffer pad PO may protrude upwards (e.g., toward the z-axis direction) on the third pad layer P3. In a plan view, the upper surface of the buffer pad PO may be seen as being included in the upper surface of the first pad layer P1.

For example, the buffer pad PO may include the first-1 buffer pad PO1-1 and the first-2 buffer pad PO1-2. For example, the buffer pad PO may further include other buffer pads. In a plan view, the first-1 buffer pad PO1-1 and the first-2 buffer pad PO1-2 may be apart in the y-axis direction. For example, the y-axis direction may be a direction that intersects a direction in which the straight line SX as described in one or more embodiments extends.

The fourth pad layer P4 may be on the third pad layer P3 and the buffer pad PO. For example, the fourth pad layer P4 may cover the upper surface and the outer surface of the buffer pad PO. The fourth pad layer P4 may include substantially the same material as and be formed or provided concurrently (e.g., simultaneously) with a second conductive layer 140 as described in one or more embodiments. The fourth pad layer P4 may include a conductive (e.g., electrically conductive) material and may be formed or provided through substantially the same process as the second conductive layer 140 was formed or provided.

As illustrated in FIG. 5, the first-1 buffer pad PO1-1 may be on the third pad layer P3. The first-1 buffer pad PO1-1 may protrude upwards (e.g., toward the z-axis direction) on the third pad layer P3. In a plan view, the upper surface of the first-1 buffer pad PO1-1 may be seen as being included in the upper surface of the first pad layer P1. The fourth pad layer P4 may be on the third pad layer P3 and the first-1 buffer pad PO1-1. For example, the fourth pad layer P4 may cover the upper surface and the outer surface of the first-1 buffer pad PO1-1. For convenience of explanation, only the first-1 buffer pad PO1-1 is illustrated in FIG. 5, but the description of the first-1 buffer pad PO1-1 may also be applied to the first-2 buffer pad PO1-2.

As illustrated in FIG. 6, a portion of the first conductive pad PD1 where the buffer pad PO is not disposed or provided may include the first pad layer P1 on the substrate 100, the second pad layer P2 on the first pad layer P1, the third pad layer P3 on the second pad layer P2, and the fourth pad layer P4 on the third pad layer P3. The third pad opening OP3 as described in one or more embodiments may be formed or provided in the second pad layer P2, and the third pad layer P3 may be in direct contact with the first pad layer P1 through the third pad opening OP3. The third pad layer P3, which is in direct contact with the first pad layer P1 through the third pad opening OP3, may electrically connect the first pad layer P1 to the fourth pad layer P4.

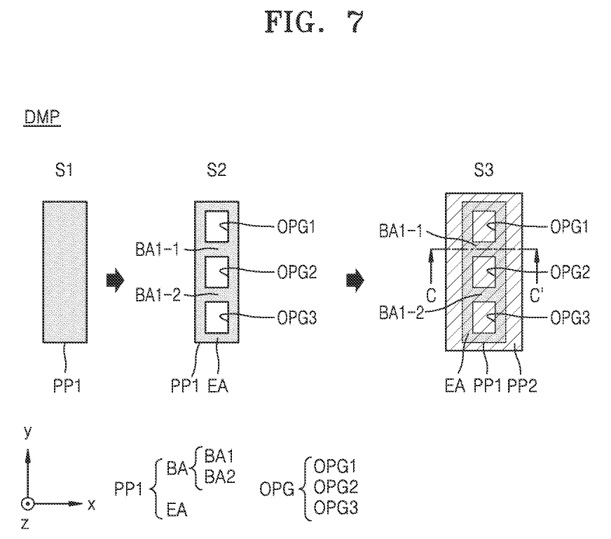

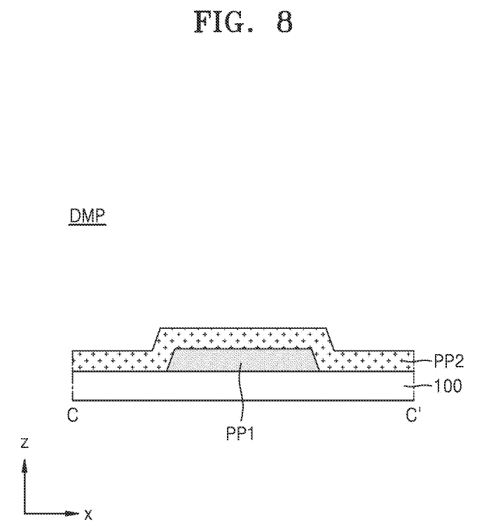

FIG. 7 is a drawing schematically illustrating the manufacturing process of the dummy pad DMP of FIGS. 1 to 3, and FIG. 8 is a schematic cross-sectional view of the dummy pad DMP of operation S3 taken along the line C-C' of FIG. 7. For reference, the description of the dummy pad DMP of FIGS. 7 and 8 may be substantially equally applied to the first dummy pad DMP1, the second dummy pad DMP2, and the third dummy pad DMP3 as described in one or more embodiments, and may also be substantially equally applied to other dummy pads that are not provided for convenience of description.

As illustrated in FIG. 7, the dummy pad DMP may include a first dummy pad layer PP1 and a second dummy pad layer PP2, and the first dummy pad layer PP1 and the second dummy pad layer PP2 may be sequentially stacked.

The dummy pad DMP1 may be manufactured through the operations as described in one or more embodiments. Other conductive (e.g., electrically conductive) pads, such as the first dummy pad DMP1, the second dummy pad DMP2, the third dummy pad DMP3, and/or the like, may also be manufactured through substantially the same methods, and, for convenience of explanation, the manufacturing method of the dummy pad DMP is described herein. For example, the manufacturing may include: forming or providing the first dummy pad layer PP1 on the substrate 100 (S1, S2); and forming or providing the second dummy pad layer PP2 on the first pad layer P1 to cover the first dummy pad layer PP1 (S3).

The forming or providing of the first dummy pad layer PP1 (S1, S2) may be performed concurrently (e.g., simultaneously) with the forming or providing of the first pad layer P1 (S10) as described in one or more embodiments. Although described separately for convenience of explanation, the forming or providing of the first dummy pad layer PP1 (S1, S2) and the forming or providing of the first pad layer P1 (S10) may be substantially the same process performed concurrently (e.g., simultaneously).

The forming or providing of the first dummy pad layer PP1 (S1, S2) may include forming or providing the first dummy pad layer (PP1) having a set or predetermined shape and/or a set or predetermined pattern on the substrate 100. The first dummy pad layer PP1 may be formed or provided through CVD and/or ALD (S1). The first dummy pad layer PP1 may be formed or provided to have a set or predetermined shape and/or a set or predetermined pattern through a dry etching process and/or a wet etching process using a mask (S2). The first dummy pad layer PP1 and the first pad layer P1 may have substantially the same shape in a plan view.

The forming or providing of the first dummy pad layer PP1 (S1) may include forming or providing a dummy opening OPG of a set or predetermined size in the first dummy pad layer PP1 after forming or providing the first dummy pad layer PP1. The dummy opening OPG formed or provided in the first dummy pad layer PP1 may include at least one dummy opening. The process of forming or providing the dummy opening OPG in the first dummy pad layer PP1 may be performed concurrently (e.g., simultaneously) with the process of forming or providing a pad opening in the first pad layer P1 as described in one or more embodiments.

Although a first dummy opening OPG1, a second dummy opening OPG2, and a third dummy opening OPG3 are illustrated in FIG. 7, they are only examples for convenience of explanation, and other dummy openings may be further formed or provided in the first dummy pad layer PP1. The dummy opening OPG may be formed or provided to have a set or predetermined shape and/or a set or predetermined pattern through a dry etching process and/or a wet etching process using a mask.

As a result of forming or providing the dummy opening OPG, the first dummy pad layer PP1 may include a bridge area BA and an edge area EA. For example, the dummy opening OPG may be defined by the bridge area BA and the edge area EA. A portion of the upper surface of the substrate 100 may be exposed upward through the dummy opening OPG.

For example, the bridge area BA may refer to a plurality of bridge areas, and the bridge area BA may include a first-1 bridge area BA1-1 and a first-2 bridge area BA1-2. For convenience of explanation, only the first-1 bridge area BA1-1 and the first-2 bridge area BA1-2 are illustrated in FIG. 7, but the bridge area BA may further include other bridge areas. The bridge area BA may extend in the x-direction in a plan view.

For example, the edge area EA may be around (e.g., surround) the dummy opening OPG and the bridge area BA in a plan view. The edge area EA may refer to an area that excludes the dummy opening OPG and the bridge area BA in the first dummy pad layer PP1 in a plan view.

For example, the first dummy opening OPG1 may be defined by the first-1 bridge area BA1-1 and the edge area EA. The second dummy opening OPG2 may be defined by the first-1 bridge area BA1-1, the first-2 bridge area BA1-2, and the edge area EA. The third dummy opening OPG3 may be defined by the first-2 bridge area BA1-2 and the edge area EA.

The first dummy opening OPG1 to the third dummy opening OPG3 may be apart from each other in the y-axis direction in a plan view. The first-1 bridge area BA1-1 and the first-2 bridge area BA1-2 may be apart in the y-axis direction in a plan view.

The forming or providing of the second dummy pad layer PP2 (S3) may include forming or providing the second dummy pad layer PP2 to cover the first dummy pad layer PP1. The second dummy pad layer PP2 may cover the upper surface of the first dummy pad layer PP1 and a portion of the upper surface of the substrate 100 exposed upward through the dummy opening OPG.

As illustrated in FIG. 8, the first dummy pad layer PP1 may be on the substrate 100. The first dummy pad layer PP1 may include substantially the same material as and be formed or provided concurrently (e.g., simultaneously) with a gate layer 120 as described in one or more embodiments. The first dummy pad layer PP1 may include a conductive (e.g., electrically conductive) material. The first dummy pad layer PP1 and the gate layer 120 may be formed or provided through substantially the same process. The first dummy pad layer PP1 and the first pad layer P1 may include substantially the same material and may be formed or provided through substantially the same process.

The second dummy pad layer PP2 may be on the first dummy pad layer PP1. The second dummy pad layer PP2 may cover the upper surface and the outer surface of the first dummy pad layer PP1. The second dummy pad layer PP2 and the interlayer insulating film 103 as described in one or more embodiments may include substantially the same material and be formed or provided concurrently (e.g., simultaneously). The second dummy pad layer PP2 may include an insulating (e.g., electrically insulating) material. The second dummy pad layer PP2 and the interlayer insulating film 103 may be formed or provided through substantially the same process. The second dummy pad layer PP2 and the second pad layer P2 may include substantially the same material and may be formed or provided through substantially the same process.

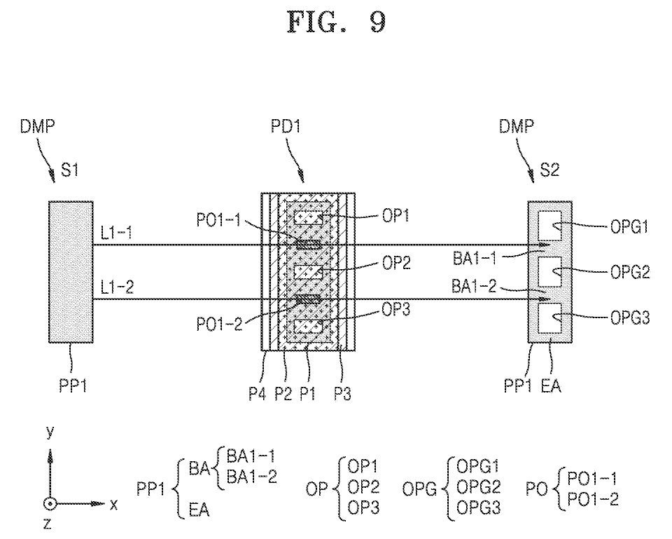

FIG. 9 is a plan view schematically illustrating an example of a method in which the first dummy pad layer PP1 of FIGS. 7 and 8 indicates the position of the buffer pad PO. For reference, FIG. 9 is a drawing illustrating a dummy pad DMP and a first conductive pad PD1 disposed or provided side by side in one display apparatus. For convenience of explanation, the first conductive pad PD1 is illustrated, but the description of the first conductive pad PD1 may be substantially equally applied to other conductive (e.g., electrically conductive) pads.

As illustrated in FIG. 9, the bridge area BA of the dummy pad DMP may be a marker to indicate the position of the buffer pad PO of the first conductive pad PD1. For example, assuming that the first dummy pad DMP1 layer of the dummy pad DMP and the first pad layer P1 of the first conductive pad PD1 (having substantially the same shape and size) are disposed or provided at substantially the same reference position, the position of the bridge area BA of the dummy pad DMP may correspond to the position of the buffer pad PO of the first conductive pad PD1.

For example, the first-1 bridge area BA1-1 may correspond to the position of the first-1 buffer pad PO1-1. For example, the first-1 bridge area BA1-1 may be on a first-1 virtual line L1-1 that passes the first-1 buffer pad PO1-1. The first-1 virtual line L1-1 may be a virtual line parallel (e.g., substantially parallel) to the x-axis direction on a plane (e.g., in a plan view). The first-1 virtual line L1-1 may be in a direction that intersects a direction in which the first-1 buffer pad PO1-1 and the first-2 buffer pad PO1-2 are apart from each other (e.g., the y-axis direction).

For example, the first-2 bridge area BA1-2 may correspond to the position of the first-2 buffer pad PO1-2. For example, the first-2 bridge area BA1-2 may be on a first-2 virtual line L1-2 that passes the first-2 buffer pad PO1-2. The first-2 virtual line L1-2 may be a virtual line parallel (e.g., substantially parallel) to the x-axis direction on a plane (e.g., in a plan view). The first-2 virtual line L1-2 may be parallel (e.g., substantially parallel) to the first-1 virtual line L1-1 on a plane (e.g., in a plan view).

For example, the bridge area BA of the dummy pad DMP may further include other bridge areas. For example, an nth virtual line may pass through an nth buffer pad and an nth bridge area concurrently (e.g., simultaneously), and the nth virtual line may be parallel (e.g., substantially parallel) to the first-1 virtual line L1-1.

For convenience of explanation, the description of FIG. 9 may be substantially equally applied to other dummy pads, such as the first dummy pad DMP1, the second dummy pad DMP2, and the third dummy pad DMP3. For example, the shape of the first dummy pad DMP1, the second dummy pad DMP2, and the third dummy pad DMP3 on a plane (e.g., in a plan view) may be substantially the same. For example, the shape of the first dummy pad DMP1 and other dummy pads on a plane (e.g., in a plan view) may be substantially the same.

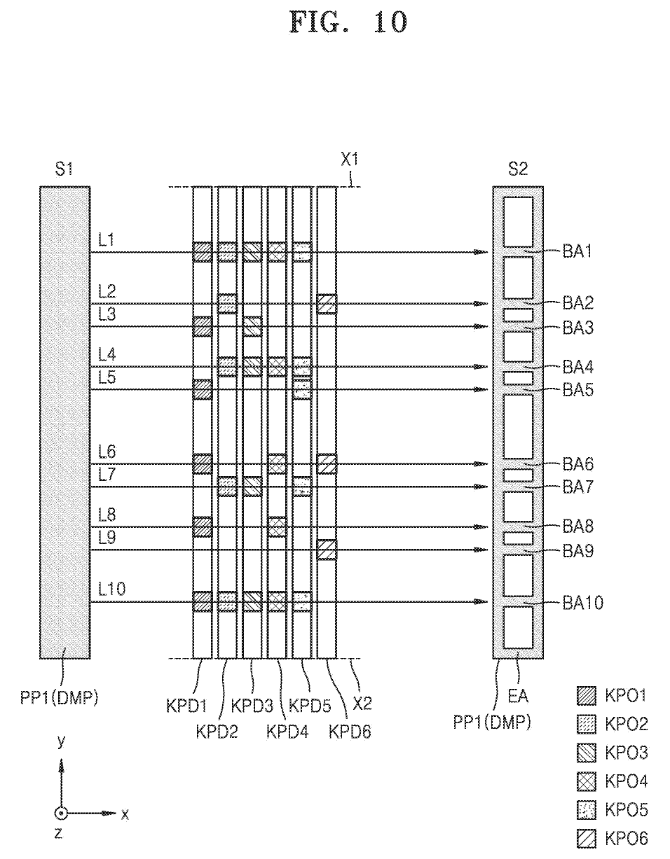

FIG. 10 is a plan view schematically illustrating an example of a method in which the first dummy pad layer PP1 of FIGS. 7 and 8 indicates the position of the buffer pad PO.

For reference, FIG. 10 is illustrated under the assumption that the dummy pad DMP or the first dummy pad layer PP1 and the conductive (e.g., electrically conductive) pads included in different display apparatuses are disposed or provided side by side. For example, the dummy pad DMP may be included in a first display apparatus, and a first pad KPD1 may also be included in the first display apparatus. However, FIG. 10 may be illustrated under the assumption that a second pad KPD2 and/or the like are included in a display apparatus other than the first display apparatus and are disposed or provided side by side with the first pad KPD1 and the dummy pad DMP.

For example, the first pad KPD1, the second pad KPD2, the third pad KPD3, the fourth pad KPD4, the fifth pad KPD5, and the sixth pad KPD6 of FIG. 10 may have substantially the same specification, and FIG. 10 is illustrated under the assumption that each of the first pad KPD1, the second pad KPD2, the third pad KPD3, the fourth pad KPD4, the fifth pad KPD5, and the sixth pad KPD6 is disposed or provided such that both (e.g., simultaneously) ends are aligned with a first straight line X1 and a second straight line X2. The first line X1 and the second line X2 may refer to parallel (e.g., substantially parallel) virtual straight lines (e.g., substantially straight lines).

As illustrated in FIG. 10, the bridge area BA of the first dummy pad layer PP1 may indicate the position of the buffer pad PO of the conductive pad PD having different designs. For example, the first pad KPD1 may refer to a conductive (e.g., electrically conductive) pad of the first display apparatus, and the second pad KPD2 may refer to a conductive (e.g., electrically conductive) pad of the second display apparatus. For example, the third pad KPD3, the fourth pad KPD4, the fifth pad KPD5, and the sixth pad KPD6 may refer to conductive (e.g., electrically conductive) pads included in a third display apparatus, a fourth display apparatus, a fifth display apparatus, and a sixth display apparatus, respectively.

The first buffer pad KPO1 may be a polymer pad included in the first pad KPD1, the second buffer pad KPO2 may be a polymer pad included in the second pad KPD2, the third buffer pad KPO3 may be a polymer pad included in the third pad KPD3, the fourth buffer pad KPO4 may be a polymer pad included in the fourth pad KPD4, the fifth buffer pad KPO5 may be a polymer pad included in the fifth pad KPD5, and the sixth buffer pad KPO6 may be a polymer pad included in the sixth pad KPD6.

For convenience of explanation, only the first pad KPD1 to the sixth pad KPD6 and the first buffer pad KPO1 to the sixth buffer pad KPO6 are illustrated in FIG. 10, but other pads included in other display apparatuses and other buffer pads included in other pads may be disclosed. In one or more embodiments, the bridge area BA of the first dummy pad DMP1 may further include other bridge areas that correspond to other buffer pads.

For example, the first dummy pad layer PP1 may include a first bridge area BA1 that corresponds to a position of a buffer pad on a first virtual line L1 among the first buffer pad KPO1 to the sixth buffer pad KPO6. For example, the first bridge area BA1 may be a marker that indicates the positions of the buffer pads on the first virtual line L1.

For example, the first dummy pad layer PP1 may include a second bridge area BA2 that corresponds to a position of a buffer pad on a second virtual line L2 among the first buffer pad KPO1 to the sixth buffer pad KPO6. The second bridge area BA2 may be a marker that indicates the positions of the buffer pads on the second virtual line L2. The second virtual line L2 may be parallel (e.g., substantially parallel) to the first virtual line L1 and may be apart from the first virtual line L1 in the longitudinal direction of the first dummy pad layer PP1 or the y-axis direction. The second bridge area BA2 may be apart from the first bridge area BA1 in the longitudinal direction of the first dummy pad layer PP1 or the y-axis direction.

For example, the first dummy pad layer PP1 may include a third bridge area BA3 that corresponds to a position of a buffer pad on a third virtual line L3 among the first buffer pad KPO1 to the sixth buffer pad KPO6. The third bridge area BA3 may be a marker that indicates the positions of the buffer pads on the third virtual line L3. The third virtual line L3 may be parallel (e.g., substantially parallel) to the second virtual line L2 and may be apart from the second virtual line L2 in the longitudinal direction of the first dummy pad layer PP1 or the y-axis direction. The second virtual line L2 may be between the first virtual line L1 and the third virtual line L3 on a plane (e.g., in a plan view). The third bridge area BA3 may be apart from the second bridge area BA2 in the longitudinal direction of the first dummy pad layer PP1 or the y-axis direction. The second bridge area BA2 may be between the first bridge area BA1 and the third bridge area BA3 on a plane (e.g., in a plan view).

For example, the first dummy pad layer PP1 may include a fourth bridge area BA4 that corresponds to a position of a buffer pad on a fourth virtual line L4 among the first buffer pad KPO1 to the sixth buffer pad KPO6. The fourth bridge area BA4 may be a marker that indicates the positions of the buffer pads on the fourth virtual line L4. The fourth virtual line L4 may be parallel (e.g., substantially parallel) to the third virtual line L3 and may be apart from the third virtual line L3 in the longitudinal direction of the first dummy pad layer PP1 or the y-axis direction. The third virtual line L3 may be between the second virtual line L2 and the fourth virtual line L4 on a plane (e.g., in a plan view). The fourth bridge area BA4 may be apart from the third bridge area BA3 in the longitudinal direction of the first dummy pad layer PP1 or the y-axis direction. The third bridge area BA3 may be between the second bridge area BA2 and the fourth bridge area BA4 on a plane (e.g., in a plan view).

For example, the first dummy pad layer PP1 may include a fifth bridge area BA5 that corresponds to a position of a buffer pad on a fifth virtual line L5 among the first buffer pad KPO1 to the sixth buffer pad KPO6. The fifth bridge area BA5 may be a marker that indicates the positions of the buffer pads on the fifth virtual line L5. The fifth virtual line L5 may be parallel (e.g., substantially parallel) to the fourth virtual line L4 and may be apart from the fourth virtual line L4 in the longitudinal direction of the first dummy pad layer PP1 or the y-axis direction. The fourth virtual line L4 may be between the third virtual line L3 and the fifth virtual line L5 on a plane (e.g., in a plan view). The fifth bridge area BA5 may be apart from the fourth bridge area BA4 in the longitudinal direction of the first dummy pad layer PP1 or the y-axis direction. The fourth bridge area BA4 may be between the third bridge area BA3 and the fifth bridge area BA5 on a plane (e.g., in a plan view).

For example, the first dummy pad layer PP1 may include a sixth bridge area BA6 that corresponds to a position of a buffer pad on a sixth virtual line L6 among the first buffer pad KPO1 to the sixth buffer pad KPO6. The sixth bridge area BA6 may be a marker that indicates the positions of the buffer pads on the sixth virtual line L6. The sixth virtual line L6 may be parallel (e.g., substantially parallel) to the fifth virtual line L5 and may be apart from the fifth virtual line L5 in the longitudinal direction of the first dummy pad layer PP1 or the y-axis direction. The fifth virtual line L5 may be between the fourth virtual line L4 and the sixth virtual line L6 on a plane (e.g., in a plan view). The sixth bridge area BA6 may be apart from the fifth bridge area BA5 in the longitudinal direction of the first dummy pad layer PP1 or the y-axis direction. The fifth bridge area BA5 may be between the fourth bridge area BA4 and the sixth bridge area BA6 on a plane (e.g., in a plan view).

For example, the first dummy pad layer PP1 may include a seventh bridge area BA7 that corresponds to a position of a buffer pad on a seventh virtual line L7 among the first buffer pad KPO1 to the sixth buffer pad KPO6. The seventh bridge area BA7 may be a marker that indicates the positions of the buffer pads on the seventh virtual line L7. The seventh virtual line L7 may be parallel (e.g., substantially parallel) to the sixth virtual line L6 and may be apart from the sixth virtual line L6 in the longitudinal direction of the first dummy pad layer PP1 or the y-axis direction. The sixth virtual line L6 may be between the fifth virtual line L5 and the seventh virtual line L7 on a plane (e.g., in a plan view). The seventh bridge area BA7 may be apart from the sixth bridge area BA6 in the longitudinal direction of the first dummy pad layer PP1 or the y-axis direction. The sixth bridge area BA6 may be between the fifth bridge area BA5 and the seventh bridge area BA7 on a plane (e.g., in a plan view).

For example, the first dummy pad layer PP1 may include an eighth bridge area BA8 that corresponds to a position of a buffer pad on an eighth virtual line L8 among the first buffer pad KPO1 to the sixth buffer pad KPO6. The eighth bridge area BA8 may be a marker that indicates the positions of the buffer pads on the eighth virtual line L8. The eighth virtual line L8 may be parallel (e.g., substantially parallel) to the seventh virtual line L7 and may be apart from the seventh virtual line L7 in the longitudinal direction of the first dummy pad layer PP1 or the y-axis direction. The seventh virtual line L7 may be between the sixth virtual line L6 and the eighth virtual line L8 on a plane (e.g., in a plan view). The eighth bridge area BA8 may be apart from the seventh bridge area BA7 in the longitudinal direction of the first dummy pad layer PP1 or the y-axis direction. The seventh bridge area BA7 may be between the sixth bridge area BA6 and the eighth bridge area BA8 on a plane (e.g., in a plan view).

For example, the first dummy pad layer PP1 may include a ninth bridge area BA5 that corresponds to a position of a buffer pad on a ninth virtual line L9 among the first buffer pad KPO1 to the sixth buffer pad KPO6. The ninth bridge area BA9 may be a marker that indicates the positions of the buffer pads on the ninth virtual line L9. The ninth virtual line L9 may be parallel (e.g., substantially parallel) to the eighth virtual line L8 and may be apart from the eighth virtual line L8 in the longitudinal direction of the first dummy pad layer PP1 or the y-axis direction. The eighth virtual line L8 may be between the seventh virtual line L7 and the ninth virtual line L9 on a plane (e.g., in a plan view). The ninth bridge area BA9 may be apart from the eighth bridge area BA8 in the longitudinal direction of the first dummy pad layer PP1 or the y-axis direction. The eighth bridge area BA8 may be between the seventh bridge area BA7 and the ninth bridge area BA9 on a plane (e.g., in a plan view).

For example, the first dummy pad layer PP1 may include a tenth bridge area BA10 that corresponds to a position of a buffer pad on a tenth virtual line L10 among the first buffer pad KPO1 to the sixth buffer pad KPO6. The tenth bridge area BA10 may be a marker that indicates the positions of the buffer pads on the tenth virtual line L10. The tenth virtual line L10 may be parallel (e.g., substantially parallel) to the ninth virtual line L9 and may be apart from the ninth virtual line L9 in the longitudinal direction of the first dummy pad layer PP1 or the y-axis direction. The ninth virtual line L9 may be between the eighth virtual line L8 and the tenth virtual line L10 on a plane (e.g., in a plan view). The tenth bridge area BA10 may be apart from the ninth bridge area BA9 in the longitudinal direction of the first dummy pad layer PP1 or the y-axis direction. The ninth bridge area BA9 may be between the eighth bridge area BA8 and the tenth bridge area BA10 on a plane (e.g., in a plan view).

In one or more embodiments, other virtual lines may be disclosed or provided, and other bridge areas may be disposed or provided to indicate the positions of buffer pads on other virtual lines.

For example, in the case of the first display apparatus of FIG. 10, the buffer pads of the first display apparatus may be respectively disposed or provided on the first virtual line L1, the third virtual line L3, the fifth virtual line L5, the sixth virtual line L6, the eighth virtual line L8, and the tenth virtual line L10. Therefore, a user or an inspector may obtain additional information about the first bridge area, the third bridge area, the fifth bridge area, the sixth bridge area, the eighth bridge area, and the tenth bridge area in advance, and may easily know the position of each of the buffer pads included in the conductive (e.g., electrically conductive) pad of the first display apparatus using only the dummy pad DMP based on the obtained additional information.

For example, in the case of the second display apparatus of FIG. 10, the buffer pads of the second display apparatus may be respectively disposed or provided on the first virtual line L1, the second virtual line L2, the fourth virtual line L4, the seventh virtual line L7, and the tenth virtual line L10. Therefore, a user or an inspector may obtain additional information about the first bridge area, the second bridge area, the fourth bridge area, the seventh bridge area, and the tenth bridge area in advance, and may easily know the position of each of the buffer pads included in the conductive (e.g., electrically conductive) pad of the second display apparatus using only the dummy pad DMP based on the obtained additional information.

For example, in the case of the third display apparatus of FIG. 10, the buffer pads of the third display apparatus may be respectively disposed or provided on the first virtual line L1, the third virtual line L3, the fourth virtual line L4, the seventh virtual line L7, and the tenth virtual line L10. Therefore, a user or an inspector may obtain additional information about the first bridge area, the third bridge area, the fourth bridge area, the seventh bridge area, and the tenth bridge area in advance, and may easily know the position of each of the buffer pads included in the conductive (e.g., electrically conductive) pad of the second display apparatus using only the dummy pad DMP based on the obtained additional information.

For example, in the case of the fourth display apparatus of FIG. 10, the buffer pads of the fourth display apparatus may be respectively disposed or provided on the first virtual line L1, the fourth virtual line L4, the sixth virtual line L6, the eighth virtual line L8, and the tenth virtual line L10. Therefore, a user or an inspector may obtain additional information about the first bridge area, the fourth bridge area, the sixth bridge area, the eighth bridge area, and the tenth bridge area in advance, and may easily know the position of each of the buffer pads included in the conductive (e.g., electrically conductive) pad of the fourth display apparatus using only the dummy pad DMP based on the obtained additional information.

For example, in the case of the fifth display apparatus of FIG. 10, the buffer pads of the fifth display apparatus may be respectively disposed or provided on the first virtual line L1, the fourth virtual line L4, the fifth virtual line L5, the seventh virtual line L7, and the tenth virtual line L10. Therefore, a user or an inspector may obtain additional information about the first bridge area, the fourth bridge area, the fifth bridge area, the seventh bridge area, and the tenth bridge area in advance, and may easily know the position of each of the buffer pads included in the conductive (e.g., electrically conductive) pad of the fifth display apparatus using only the dummy pad DMP based on the obtained additional information.

For example, in the case of the sixth display apparatus of FIG. 10, the buffer pads of the sixth display apparatus may be respectively disposed or provided on the second virtual line L2, the sixth virtual line L6, and the ninth virtual line L9. Therefore, a user or an inspector may obtain additional information about the second bridge area, the sixth bridge area, and the ninth bridge area in advance, and may easily know the position of each of the buffer pads included in the conductive (e.g., electrically conductive) pad of the sixth display apparatus using only the dummy pad DMP based on the obtained additional information.

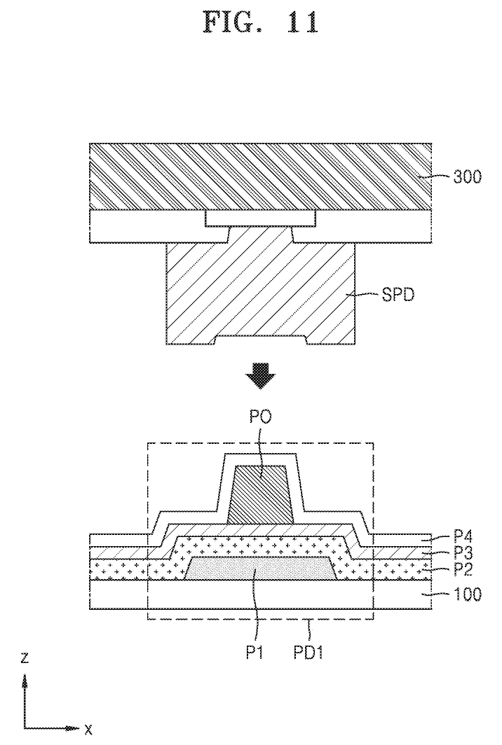

FIG. 11 is a schematic cross-sectional view of the first conductive pad PD1 and a signal pad SPD of FIG. 1.

For convenience of explanation, the first conductive pad PD1 of FIG. 11 is illustrated mainly or predominantly with respect to the buffer pad PO, and only a portion of the printed circuit board 300 is illustrated. Although only the first conductive pad PD1 is shown, substantially the same description may be applied to the other conductive (e.g., electrically conductive) pads.

As illustrated in FIG. 11, the first conductive pad PD1 may protrude upward by the buffer pad PO, and the signal pad SPD that protrudes downward may be in direct contact with the first conductive pad PD1 that protrudes upward. The lower surface of the signal pad SPD may be concave to correspond to the protruding shape of the first conductive pad PD1. The concave shape of the lower surface of the signal pad SPD may correspond to the protruding shape of the upper surface of the first conductive pad PD1, thereby allowing the signal pad SPD to be brought into exact contact with the first conductive pad PD1 at a desired position.

In one or more embodiments, the display apparatus of the Comparative Example may form or provide a protrusion on the pad by using a conductive (e.g., electrically conductive) ball. If (e.g., when) using the conductive ball, it may be difficult to dispose or provide the conductive ball in the exact position. For example, it may be difficult to control the position of the conductive ball. Because it is difficult to control the position of the conductive ball, it may be difficult to form or provide pad protrusions by using the conductive ball at high resolution. In one or more embodiments, short circuits may occur between pads due to the difficulty in controlling the position of the conductive ball.

In one or more embodiments, if (e.g., when) forming or providing a protrusion on the conductive pad PD using the buffer pad PO, because the buffer pad PO is formed or provided using a mask process, the protrusion may be formed or provided at an exact desired position. Therefore, substantially all difficulties of the Comparative Example may be resolved.

The user or inspector may easily find the position of the buffer pad PO included in the conductive pad PD by using the bridge area BA of the dummy pad DMP disposed or provided parallel (e.g., substantially parallel) to the conductive pad PD. In one or more embodiments, as shown in FIG. 10, even if (e.g., when) the positions of the buffer pads PO in each display apparatus are different, the dummy pads DMP that respectively correspond to the display apparatuses may be formed or provided with one mask. Therefore, the process as described in one or more embodiments may be economical because generating a plurality of masks that corresponds to each display apparatus is not desired or required. As in FIG. 10, if (e.g., when) one type or kind of dummy pad DMP indicates the positions of different types or kinds of buffer pads PO, the user or inspector may easily know the positions of the buffer pads PO based on additional information that corresponds to each display apparatus.

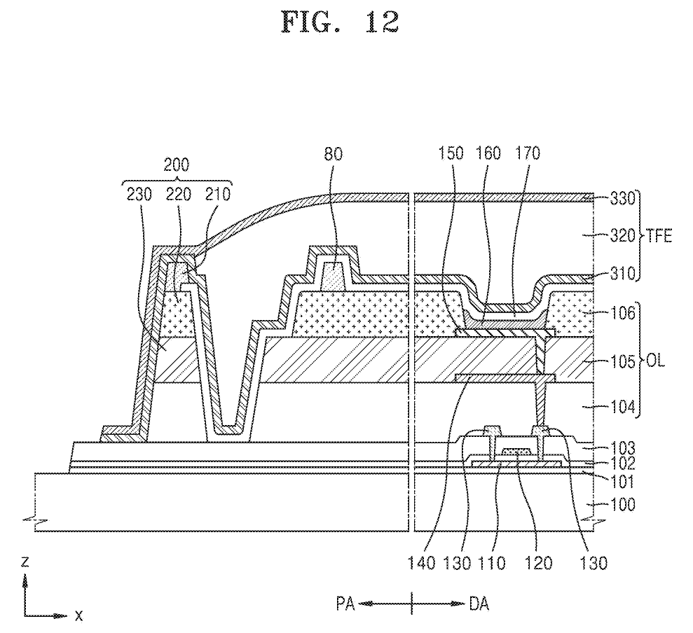

FIG. 12 is a schematic cross-sectional view of a portion of a pixel of FIG. 1. For convenience of explanation, any content of FIG. 12 that is substantially identical or overlapping with the content as described in one or more embodiments may not be provided.

The substrate 100 may include, as described in one or more embodiments, areas that correspond to the display area DA and the peripheral area PA outside the display area DA. The substrate 100 may include one or more suitable flexible materials and/or bendable materials. For example, the substrate 100 may include glass, metal, and/or a polymer resin. Furthermore, the substrate 100 may include a polymer resin, such as polyethersulfone, polyacrylate, polyetherimide, polyethylene naphthalate, polyethylene terephthalate, polyphenylene sulfide, polyarylate, polyimide, polycarbonate, and/or cellulose acetate propionate. The substrate 100 may have one or more suitable modifications, for example, a multiplayer structure of two layers each including a polymer resin as described in one or more embodiments and a barrier layer between the two layers and including an inorganic material, such as a silicon oxide, a silicon nitride, a silicon oxynitride, and/or the like.

The buffer layer 101 may be on the substrate 100. The buffer layer 101 may prevent diffusion of impurities ions and/or infiltration of moisture and/or external air (or reduce a degree or occurrence of diffusion of impurities ions and/or infiltration of moisture and/or external air) and may serve as a barrier layer to planarize a surface and/or a blocking layer. The buffer layer 101 may include a silicon oxide, a silicon nitride, and/or a silicon oxynitride. Furthermore, the buffer layer 101 may control a heat supply speed during a crystallization process for forming or providing a semiconductor layer 110, to uniformly (e.g., substantially uniformly) crystalize the semiconductor layer 110.

The semiconductor layer 110 may be on the buffer layer 101. The semiconductor layer 110 may be made of polysilicon and include a channel region that is not doped with impurities, and a source region and a drain region formed or provided in both sides (e.g., two opposing sides) of the channel region and doped with impurities. The impurities may vary depending on the type or kind of the thin-film transistor and may be, for example, negative type or kind (N-type or kind) impurities and/or positive type or kind (P-type or kind) impurities.

A gate insulating film 102 may be on the semiconductor layer 110. The gate insulating film 102 may be provided to secure or provide insulation (e.g., electrical insulation) between the semiconductor layer 110 and a gate layer 120. The gate insulating film 102 may include a silicon oxide, a silicon nitride, a silicon oxynitride, and/or the like and may be provided between the semiconductor layer 110 and the gate layer 120. Furthermore, the gate insulating film 102 may be formed or provided on the entire surface of the substrate 100 and may have a structure in which contact holes are formed or provided in preset portions. As such, an insulating (e.g., electrically insulating) film including an inorganic material may be formed or provided through chemical vapor deposition (CVD) and/or atomic layer deposition (ALD). This applies to one or more embodiments and modifications thereof as described in one or more embodiments in substantially the same manner.

The gate layer 120 may be on the gate insulating film 102. The gate layer 120 may be at a position that vertically overlaps the semiconductor layer 110 and may include at least one of a metal selected from among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu).

An interlayer insulating film 103 may be on the gate layer 120. The interlayer insulating film 103 may cover the gate layer 120. The interlayer insulating film 103 may include an inorganic material. For example, the interlayer insulating film 103 may include a metal oxide and/or a metal nitride, and in more detail, the inorganic material may include a silicon oxide (e.g., SiOₓ,wherein 0 < x ≤ 2; e.g., SiO₂), a silicon nitride (e.g., Si₃N₄ or SiNₓ, wherein 0 < x ≤ 2), a silicon oxynitride (e.g., Si₂N₂O or SiOₓN_{y}, wherein 0 < x ≤ 2 and 0 ≤ y ≤ 2; e.g., SiON), an aluminum oxide (e.g., Al₂O₃), a titanium oxide (e.g., TiOₓ, wherein 0 < x ≤ 2; e.g., TiO₂), a tantalum oxide (e.g., Ta₂O₅), a hafnium oxide (e.g., HfO₂), a zinc oxide (e.g., ZnO), and/or the like. In one or more embodiments, the interlayer insulating film 103 may have a dual structure of SiOₓ/SiN_{y} or SiNₓ/SiO_{y}.

The first conductive layer 130 may be on the interlayer insulating film 103. The first conductive layer 130 may serve as an electrode connected to the source/drain regions of the semiconductor layer via a through-hole formed or provided in the interlayer insulating film 103. The first conductive layer 130 may include one or more metals selected from among Al, Pt, Pd, Ag, Mg, Au, Ni, Nd, Ir, Cr, Li, Ca, Mo, Ti, W, and Cu. For example, the first conductive layer 130 may include a Ti layer, an Al layer, and/or a Cu layer.

A first organic insulating layer 104 may be on the first conductive layer 130. The first organic insulating layer 104 that covers the first conductive layer 130 and has a substantially flat upper surface may be an organic insulating (e.g., electrically insulating) layer that serves as a planarized film. The first organic insulating layer 104 may include an organic material, such as acryl, benzocyclobutene (BCB), hexamethyldisiloxane (HMDSO), and/or the like. The first organic insulating layer 104 may be suitably modified, for example, to have a single layer structure, a multi-layer structure, and/or the like.

The second conductive layer 140 may be on the first organic insulating layer 104. The second conductive layer 140 may serve as an electrode connected to the source/drain regions of the semiconductor layer via a through-hole formed or provided in the first organic insulating layer 104. The second conductive layer 140 may include one or more metals selected from among Al, Pt, Pd, Ag, Mg, Au, Ni, Nd, Ir, Cr, Li, Ca, Mo, Ti, W, and Cu. For example, the second conductive layer 140 may include a Ti layer, an Al layer, and/or a Cu layer.

A second organic insulating layer 105 may be on the second conductive layer 140. The second organic insulating layer 105 that covers the second conductive layer 140 and has a substantially flat upper surface may be an organic insulating (e.g., electrically insulating) layer that serves as a planarized film. The second organic insulating layer 105 may include an organic material, such as acryl, BCB, HMDSO, and/or the like. The second organic insulating layer 105 may be suitably modified into, for example, a single layer, a multilayer, and/or the like.

Furthermore, in addition to one or more embodiments as illustrated in FIG. 12, one or more suitable modifications may be feasible, for example, an additional conductive (e.g., electrically conductive) layer and/or an additional insulating (e.g., electrically insulating) layer may be provided between the first conductive layer 130 and a pixel electrode 150. In one or more embodiments, the additional conductive (e.g., electrically conductive) layer may include substantially the same material and have substantially the same layer structure as the conductive (e.g., electrically conductive) layer as described in one or more embodiments. The additional insulating (e.g., electrically insulating) layer may include substantially the same material and have substantially the same layer structure as the organic insulating (e.g., electrically insulating) layer as described in one or more embodiments.

The pixel electrode 150 may be on the second organic insulating layer 105. The pixel electrode 150 may be connected to the second conductive layer 140 via a contact hole formed or provided in the second organic insulating layer 105. A display element may be on the pixel electrode 150. An organic light-emitting diode may be used as the display element. For example, the organic light-emitting diode may be disposed or provided, for example, on the pixel electrode 150. The pixel electrode 150 may include a transmissive conductive (e.g., electrically conductive) layer including a transmissive conductive (e.g., electrically conductive) oxide, such as ITO, In₂O₃, IZO, and/or the like, and a reflective layer including a metal, such as Al, Ag, and/or the like. For example, the pixel electrode 150 may have a three-layer structure of ITO/Ag/ITO.

A pixel defining film 106 may be on the second organic insulating layer 105 and cover an edge of the pixel electrode 150. For example, the pixel defining film 106 may cover the edge of the pixel electrode 150. The pixel defining film 106 may have an opening that corresponds to the subpixel PX, and the opening may be formed or provided to expose at least a central portion of the pixel electrode 150. The pixel defining film 106 may include an organic material, such as polyimide, HMDSO, and/or the like. Furthermore, a spacer 80 may be on the pixel defining layer 106.

The first organic insulating layer 104, the second organic insulating layer 105, and the pixel defining film 106 may be defined as organic material layers OL.

Although the spacer 80 is illustrated as being in the peripheral area PA, the spacer 80 may be disposed or provided in the display area DA. The spacer 80 may prevent the organic light-emitting diode from being damaged (or reduce a degree to or occurrence of which the organic light-emitting diode is damaged) due to sagging of a mask in a manufacturing process using the mask. The spacer 80 may include an organic insulating (e.g., electrically insulating) material and may be formed or provided in a single layer or a multilayer.

An intermediate layer 160 and a counter electrode 170 may be in an opening of the pixel defining film 106. The intermediate layer 160 may include a low molecular weight material and/or a high molecular weight material, and if (e.g., when) the low molecular weight material is included, the intermediate layer 160 may include a hole injection layer, a hole transport layer, an emission layer, an electron transport layer, and/or an electron injection layer. If (e.g., when) the intermediate layer 160 includes a high molecular weight material (e.g., a polymer material), the intermediate layer 160 may generally have a structure including the hole transport layer and the emission layer.

The counter electrode 170 may include a transmissive conductive (e.g., electrically conductive) layer made of a transmissive conductive (e.g., electrically conductive) oxide, such as ITO, In₂O₃, IZO, and/or the like. The pixel electrode 150 may be used as an anode and the counter electrode 170 may be used as a cathode. The polarities of the electrodes as described in one or more embodiments may be reversely applied.

The structure of the intermediate layer 160 is not limited to the description in one or more embodiments and may be suitably modified. For example, at least one selected from among the layers that form or provide the intermediate layer 160 may be integrally formed or provided with the counter electrode 170. In one or more embodiments, the intermediate layer 160 may include a layer patterned to correspond to each of the plurality of pixel electrodes 150.

The counter electrode 170 may be on the display area DA and on the entire surface of the display area DA. For example, the counter electrode 170 may be integrally formed or provided to cover a plurality of pixels. The counter electrode 170 may electrically contact a common power supply line in the peripheral area PA. In one or more embodiments, the counter electrode 170 may extend to a barrier 200. A thin-film encapsulation layer TFE may be disposed or provided to entirely cover the display area DA and extend toward the peripheral area PA to thus cover at least a portion of the peripheral area PA.

The thin-film encapsulation layer TFE may extend to the outside of the common power supply line. The thin-film encapsulation layer TFE may include a first inorganic encapsulation layer 310, a second inorganic encapsulation layer 330, and an organic encapsulation layer 320 provided therebetween. The first inorganic encapsulation layer 310 and the second inorganic encapsulation layer 330 may each include one or more inorganic materials selected from among Al₂O₃, TiO₂, Ta₂O₅, HfO₂, ZrO₂, SiO₂, SiNₓ, SiON, and SiON.

The first inorganic encapsulation layer 310 and the second inorganic encapsulation layer 330 may each be a single layer or a multilayer including a material as described in one or more embodiments. The first inorganic encapsulation layer 310 and the second inorganic encapsulation layer 330 may include substantially the same material or different materials. The first inorganic encapsulation layer 310 and the second inorganic encapsulation layer 330 may have different thicknesses. The thickness of the first inorganic encapsulation layer 310 may be greater than the thickness of the second inorganic encapsulation layer 330. In one or more embodiments, the thickness of the second inorganic encapsulation layer 330 may be greater than the thickness of the first inorganic encapsulation layer 310, or the thicknesses of the first inorganic encapsulation layer 310 and the second inorganic encapsulation layer 330 may be substantially identical to each other.

The organic encapsulation layer 320 may include a monomer-based material and/or a polymer-based material. Examples of the polymer-based material may include an acrylic resin, an epoxy resin, polyimide, and/or polyethylene. According to one or more embodiments, the organic encapsulation layer 320 may include acrylate.

The barrier 200 may be in the peripheral area PA on the substrate 100. In one or more embodiments, the barrier 200 may include, but is not necessarily limited to, a portion of the first organic insulating layer 104, a portion 230 of the second organic insulating layer 105, a portion 220 of the pixel defining film 106, and a portion 210 of the spacer 80.

The barrier 200 may be disposed or provided to be around (e.g., surround) the display area DA and may prevent the organic encapsulation layer 320 of the thin-film encapsulation layer TFE from overflowing to the outside of the substrate 100 (or reduce a degree to or occurrence of which the organic encapsulation layer 320 of the thin-film encapsulation layer TFE overflows to the outside of the substrate 100). The organic encapsulation layer 320 may be in contact with an inner side surface of the barrier 200 that faces the display area DA. The organic encapsulation layer 320 being in contact with the inner surface of the barrier 200 may be understood that the first inorganic encapsulation layer 310 is between the organic encapsulation layer 320 and the barrier 200, and the organic encapsulation layer 320 contacts the first inorganic encapsulation layer 310.

The first inorganic encapsulation layer 310 and the second inorganic encapsulation layer 330 may be on the barrier 200 and may extend toward an edge of the substrate 100. However, in one or more embodiments, a plurality of barriers 200 may be included.

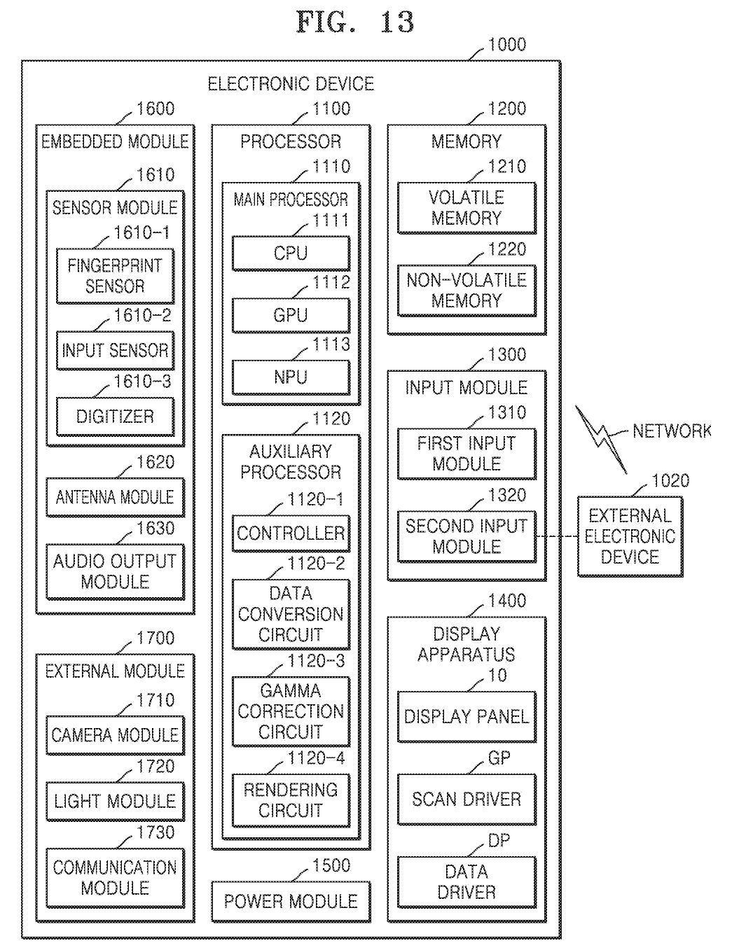

FIG. 13 is a conceptual diagram schematically illustrating an electronic device including the display apparatus of FIGS. 1 to 12.

The display panel 10 as described in FIG. 13 refers to the display apparatus, the display panel 10, and/or the like in FIGS. 1 to 12. Accordingly, description of the display panel 10 and/or the like that is substantially identical or that overlaps with the contents as described in one or more embodiments may not be provided.

A scan driver GP may receive a scan control signal from a controller 1120-1 and output scan signals to the display panel 10 in response to a scan control signal. For example, the scan control signal generated from the controller 1120-1 and transmitted to the scan driver GP may be a scan input signal to control the scan driver GP.

A data driver DP may receive a data control signal from the controller 1120-1, convert image data into analog voltages (e.g., data voltages) in response to the data control signal, and then output the data voltages to the display panel 10. For example, a data control signal generated by the controller 1120-1 and transmitted to the data driver DP may be a data input signal to control the data driver DP.

The data driver DP may be integrated into another component (e.g., the controller 1120-1). The functions of an interface conversion circuit and a timing control circuit of the controller 1120-1 as described in one or more embodiments may be integrated into the data driver DP.

The controller 1120-1 may generate a clock signal desired or required to drive the scan driver GP. The scan driver GP may operate each stage based on a clock signal that corresponds to each stage.

The scan driver GP may generate a scan signal based on the scan input signal, the clock signal, and a scan input voltage. The scan signal may be transmitted to a pixel circuit, and a thin-film transistor included in the pixel circuit may be driven based on the scan signal. The scan signal may be transmitted to a gate included in the pixel circuit.

A display apparatus 1400 may further include a light-emitting driver and a voltage generator circuit. The voltage generator circuit may output one or more voltages desired or required to drive the display panel 10.

A power module 1500 may supply power to components of the electronic device 1010. For example, the power module 1500 may generate a first power voltage and a second power voltage. The power module 1500 may generate a gate driving voltage (e.g., a gate high voltage and a gate low voltage) desired or required to drive the scan driver GP.

For example, the power module 1500 may refer to a power generator, a power supply, and/or the like. For example, the power module 1500 may include a battery that is charged with the power voltage. The battery may include a non-rechargeable primary battery, a rechargeable secondary battery, or a fuel cell.

For example, the power module 1500 may include a power management integrated circuit (PMIC). The PMIC may provide optimized power for each of the modules as described in one or more embodiments.

For example, the power module 1500 may include a wireless power transmitter/receiver member electrically connected to the battery. The wireless power transmitter/receiver member may include a plurality of coil-shaped antenna radiators.

The electronic device 1010 may further include an embedded module 1600 and an external module 1700. The embedded module 1600 may include a sensor module 1610, an antenna module 1620, and an audio output module 1630. The external module 1700 may include a camera module 1710, a light module 1720, and a communication module 1730.

The sensor module 1610 may detect an input by a user's body or an input by a pen among a first input module 1310 and generate an electric signal or a data value that corresponds to the input. The sensor module 1610 may include at least one selected from among a fingerprint sensor 1610-1, an input sensor 1610-2, and a digitizer 1610-3.

The fingerprint sensor 1610-1 may generate a data value that corresponds to the user's fingerprint. The fingerprint sensor 1610-1 may include either an optical fingerprint sensor or a capacitive fingerprint sensor.

The input sensor 1610-2 may generate data values that correspond to coordinate information of input by the user's body or input by the pen. The input sensor 1610-2 may generate a data value based on a change in capacitance due to an input. The input sensor 1610-2 may detect input by a passive pen or transmit and receive data with an active pen.

The input sensor 1610-2 may also measure bio signals, such as blood pressure, moisture, and/or body fat. For example, if (e.g., when) a part of the user's body contacts a sensor layer or a sensing panel and does not move for a certain (e.g., set or predetermined) period of time, the input sensor 1610-2 may detect a bio signal based on a change in the electric field caused by the part of the body and output information desired by the user to the display module 1400.

The digitizer 1610-3 may generate data values that correspond to coordinate information input by the pen. The digitizer 1610-3 may generate a data value based on an electromagnetic change due to the input. The digitizer 1610-3 may detect input from a passive pen or transmit and receive data with an active pen.

At least one selected from among the fingerprint sensor 1610-1, the input sensor 1610-2, and the digitizer 1610-3 may be implemented as a sensor layer on the display panel 10 through a consecutive process. The fingerprint sensor 1610-1, the input sensor 1610-2, and the digitizer 1610-3 may be on the upper side of the display panel 10, and any one selected from among the fingerprint sensor 1610-1, the input sensor 1610-2, and the digitizer 1610-3, for example, the digitizer 1610-3, may be on the lower side of the display panel 10.

At least two selected from among the fingerprint sensor 1610-1, the input sensor 1610-2, and the digitizer 1610-3 may be integrated into one sensing panel through substantially the same process. Once integrated, the sensing panel may be between the display panel 10 and a window on the display panel 10. In one or more embodiments, the sensing panel may be on the window, and the position of the sensing panel is not limited thereto.

At least one selected from among the fingerprint sensor 1610-1, the input sensor 1610-2, and the digitizer 1610-3 may be embedded in the display panel 10. For example, at least one selected from among the fingerprint sensor 1610-1, the input sensor 1610-2, and the digitizer 1610-3 may be formed or provided concurrently (e.g., simultaneously) through a process of forming or providing elements (e.g., light-emitting elements, transistors, and/or the like) included in the display panel 10.

In one or more embodiments, the sensor module 1610 may generate an electrical signal or a data value that corresponds to an internal state or an external state of the electronic device 1010. The sensor module 1610 may further include, for example, a gesture sensor, a gyro sensor, a pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The antenna module 1620 may include at least one antenna to transmit signals or power to or receive signals or power from the outside. In one or more embodiments, the communication module 1730 may transmit a signal to an external electronic device or receive a signal from an external electronic device through an antenna suitable for a communication method. The antenna pattern of the antenna module 1620 may be integrated into one component of the display module 1400 (e.g., the display panel 10 or the input sensor 1610-2).

The audio output module 1630 may be configured or provided to output audio signals to the outside of the electronic device 1010 and may include, for example, a speaker used for general purposes, such as playing multimedia or playing record, and a receiver used exclusively to receive incoming calls. In one or more embodiments, the receiver may be formed or provided integrally with or separately from the speaker. The audio output pattern of the audio output module 1630 may be integrated into the display module 1400.

The camera module 1710 may capture still images and/or moving images. In one or more embodiments, the camera module 1710 may include one or more lenses, image sensors, or image signal processors. The camera module 1710 may further include an infrared camera capable of measuring the presence or absence of the user, the user's location, the user's gaze, and/or the like.

The light module 1720 may provide light. The light module 1720 may include a light-emitting diode or a xenon lamp. The light module 1720 may operate either in synchronization with the camera module 1710 or independently.

The communication module 1730 may support establishment of a wired communication channel or a wireless communication channel between the electronic device 1010 and an external electronic device 1020 and performance of communication through the established communication channel. The communication module 1730 may include one or both (e.g., simultaneously) of a wireless communication module, such as a cellular communication module, a short-range wireless communication module, or a global navigation satellite system (GNSS) communication module, and a wired communication module, such as a local area network (LAN) communication module or a power line communication module. The communication module 1730 may communicate with the external electronic device 1020 via a short-range communication network, such as Bluetooth, Wi-Fi direct, or infrared data association (IrDA), or a long-range communication network, such as a cellular network, the Internet, or a computer network (e.g., a LAN or a wide area network (WAN)). The one or more suitable types or kinds of communication modules 1730 as described in one or more embodiments may be implemented as one chip or as separate chips.

The input module 1300, the sensor module 1610, the camera module 1710, and/or the like may be used to control the operation of the display module 1400 in synchronization with the processor 1100.

The processor 1100 may output a command or data to the display module 1400, the audio output module 1630, the camera module 1710, or the light module 1720 based on input data received from the input module 1300. For example, the processor 1100 may generate image data in response to input data received through a mouse or an active pen and output the image data to the display module 1400 or generate command data in response to the input data and output the command data to the camera module 1710 or the light module 1720. If (e.g., when) input data is not received from the input module 1300 for a certain (e.g., set or predetermined) period of time, the processor 1100 may switch the operation mode of the electronic device 1010 to a low power mode or a sleep mode to reduce power consumption of the electronic device 1010.

The processor 1100 may output a command or data to the display module 1400, the audio output module 1630, the camera module 1710, or the light module 1720 based on sensing data received from the sensor module 1610. For example, the processor 1100 may compare authentication data authorized by the fingerprint sensor 1610-1 with authentication data stored in the memory 1200, and then execute an application based on a comparison result. The processor 1100 may execute a command or output corresponding image data to the display module 1400 based on sensing data detected by the input sensor 1610-2 or the digitizer 1610-3. If (e.g., when) a temperature sensor is included in the sensor module 1610, the processor 1100 may receive temperature data of the temperature measured by the sensor module 1610 and perform luminance correction, and/or the like on the image data based on the temperature data.

The processor 1100 may receive measurement data with respect to the presence or absence of the user, the user's location, the user's gaze, and/or the like from the camera module 1710. The processor 1100 may further perform luminance correction and/or the like on the image data based on the measurement data. For example, the processor 1100 to determine the presence or absence of the user through an input from the camera module 1710 may output image data in which luminance is corrected through a data conversion circuit 1120-2 or a gamma correction circuit 1120-3 to the display module 1400.

One or more components according to one or more embodiments of the present disclosure may be connected to each other via a communication method between peripheral devices, such as a bus, a general purpose input/output (GPIO), a serial peripheral interface (SPI), a mobile industry processor interface (MIPI), or an ultra path interconnect (UPI) link, to exchange signals (e.g., commands or data) with each other. The processor 1100 may communicate with the display module 1400 through an interface between each other, and, for example, may use any of the communication methods as described in one or more embodiments, and communication methods are not limited thereto.

The electronic device 1010 according to one or more embodiments may have one or more suitable forms. The electronic device 1010 may include, for example, at least one selected from among a portable communication device (e.g., a smartphone), a computer device, a portable multimedia device, a portable medical device, a camera, a wearable device, or a home appliance device. The electronic device 1010 according to one or more embodiments is not limited to the devices as described in one or more embodiments.

In one or more embodiments, the display module included in the electronic device may include the features of the display apparatus, display panel 10, and/or the like as described in one or more embodiments in FIGS. 1 to 12. Those of ordinary skill in the art may easily understand that the description of the display apparatus, the display panel 10, and/or the like as described in FIGS. 1 to 12 may be applied to the display apparatus and the display panel 10 of FIG. 13.

In one or more embodiments, the electronic device may include a memory that stores an instruction, a processor to perform an operation based on the instruction and generate a control signal, and a display apparatus to receive the control signal from the processor and display a screen based on the control signal. The control signal referred to herein may be a concept including all signals input to the display apparatus to display a screen.

In one or more embodiments, the electronic device may include a display apparatus that corresponds to FIGS. 1 to 12 as described in one or more embodiments. For example, the electronic device may include a display apparatus including the conductive pad PD and the dummy pad DMP, such as the first conductive pad PD1 and the first dummy pad DMP1 as described in one or more embodiments. Because the features of the conductive pad PD and the dummy pad DMP included in the display apparatus are substantially the same as those described in FIGS. 1 to 12, repeated descriptions may not be provided.

According to one or more embodiments, the display apparatus in which the position of the polymer pad may be easily found and the electronic device including the display apparatus may be implemented. However, the scope of the present disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While the subject matter of the present disclosure has been described with reference to the figures, it will be understood by those of ordinary skill in the art that one or more suitable changes in form and more details may be made therein without departing from the spirit and scope as defined by the following claims and equivalents thereof.

What is claimed is:

1. A display apparatus comprising:
a substrate divided into a display area and a peripheral area around the display area, the peripheral area comprising a pad area in which a first conductive pad and a first dummy pad are provided;
a gate layer on the substrate;
an interlayer insulating film on the gate layer; and
a first conductive layer on the interlayer insulating film,
wherein the first conductive pad comprises:
a first pad layer provided on the substrate and comprising substantially the same material as the gate layer;
a second pad layer provided on the first pad layer and comprising substantially the same material as the interlayer insulating film;
a third pad layer provided on the second pad layer and comprising substantially the same material as the first pad layer; and
a first-1 buffer pad on the third pad layer,
wherein the first dummy pad comprises:
a first dummy pad layer provided on the substrate, comprising substantially the same material as the gate layer, a first-1 bridge area that corresponds to a position of the first-1 buffer pad, and an edge area around the first-1 bridge area; and
a second dummy pad layer provided on the first dummy pad layer and comprising substantially the same material as the interlayer insulating film.

2. The display apparatus as claimed in claim 1, wherein the first-1 bridge area is on a first-1 virtual line that passes the first-1 buffer pad.

3. The display apparatus as claimed in claim 2, wherein the first dummy pad further comprises a dummy opening defined by the first-1 bridge area and the edge area.

4. The display apparatus as claimed in claim 2, wherein a second conductive pad is further provided in the pad area, and
the first dummy pad is provided in a straight line as the first conductive pad and the second conductive pad.

5. The display apparatus as claimed in claim 4, wherein, on a plane, the first conductive pad is between the first dummy pad and the second conductive pad.

6. The display apparatus as claimed in claim 4, wherein, on a plane, the first dummy pad is between the first conductive pad and the second conductive pad.

7. The display apparatus as claimed in claim 4, wherein a second dummy pad is further provided in the straight line on the pad area.

8. The display apparatus as claimed in claim 7, wherein the first conductive pad and the second conductive pad are between the first dummy pad and the second dummy pad on a plane.

9. The display apparatus as claimed in claim 1, wherein the first conductive pad further comprises a first-2 buffer pad on the second pad layer.

10. The display apparatus as claimed in claim 9, wherein the first dummy pad layer further comprises:
a first-2 bridge area that corresponds to a position of the first-2 buffer pad, wherein
the edge area is around the first-1 bridge area and the first-2 bridge area.

11. The display apparatus as claimed in claim 10, wherein the first-2 bridge area passes the first-2 buffer pad and is on a first-2 virtual line parallel to a first-1 virtual line that passes the first-1 buffer pad.

12. The display apparatus as claimed in claim 11, wherein each of the first-1 buffer pad and the first-2 buffer pad comprises a polymer.

13. The display apparatus as claimed in claim 1, further comprising a second conductive layer on the first conductive layer,
wherein the first conductive pad further comprises a fourth pad layer provided on the first-1 buffer pad and comprising substantially the same material as the second conductive layer.

14. The display apparatus as claimed in claim 13, wherein the fourth pad layer covers an upper surface and an outer surface of the first-1 buffer pad.

15. The display apparatus as claimed in claim 1, wherein the second pad layer comprises at least one pad opening, and
the third pad layer contacts the first pad layer via the at least one pad opening.

16. A display apparatus comprising:
a substrate comprising a display area and a peripheral area around the display area;
a first conductive pad provided in the peripheral area and comprising a first buffer pad; and
a first dummy pad in the peripheral area,
wherein the first dummy pad comprises:
a first dummy pad layer on the substrate; and
a second dummy pad layer on the first dummy pad layer,
wherein the first dummy pad layer comprises:
a first bridge area that corresponds to a position of the first buffer pad;
a second bridge area that corresponds to a position of a second buffer pad in another display apparatus; and
an edge area around the first bridge area and the second bridge area.

17. The display apparatus as claimed in claim 16, further comprising:
a gate layer on the substrate; and
an interlayer insulating film on the gate layer,
wherein the first dummy pad layer comprises substantially the same material as the gate layer, and the second dummy pad layer comprises substantially the same material as the interlayer insulating film.

18. The display apparatus as claimed in claim 16, wherein the second buffer pad is in a second conductive pad that is in the other display apparatus.

19. The display apparatus as claimed in claim 18, wherein, when the first dummy pad, the first conductive pad, and the second conductive pad are provided side by side,
the first bridge area is on a first virtual line that passes the first buffer pad, and
the second bridge area is on a second virtual line that passes the second buffer pad and that is parallel to the first virtual line.

20. An electronic device comprising:
a memory to store instructions;
a processor to generate control signals based on the instructions; and
a display apparatus to display a screen based on the control signals,
wherein the display apparatus comprises:
a substrate divided into a display area and a peripheral area around the display area, the peripheral area comprising a pad area in which a first conductive pad and a first dummy pad are provided;
a gate layer on the substrate;
an interlayer insulating film on the gate layer; and
a first conductive layer on the interlayer insulating film,
wherein the first conductive pad comprises:
a first pad layer provided on the substrate and comprising substantially the same material as the gate layer;
a second pad layer provided on the first pad layer and comprising substantially the same material as the interlayer insulating film;
a third pad layer provided on the second pad layer and comprising substantially the same material as the first pad layer; and
a first-1 buffer pad on the third pad layer,
wherein the first dummy pad comprises:
a first dummy pad layer provided on the substrate, comprising substantially the same material as the gate layer, a first-1 bridge area that corresponds to a position of the first-1 buffer pad, and an edge area around the first-1 bridge area; and
a second dummy pad layer provided on the first dummy pad layer and comprising substantially the same material as the interlayer insulating film.
